(19) United States
(12) Patent Application Publication
(10) Pub. No.: US 2025/0203882 A1
(43) Pub. Date: Jun. 19, 2025

(54) SEMICONDUCTOR DEVICE INCLUDING A STACK STRUCTURE

(71) Applicant: SK hynix Inc., Icheon-si Gyeonggi-do (KR)

(72) Inventor: Young Ock HONG, Icheon-si Gyeonggi-do (KR)

(73) Assignee: SK hynix Inc., Icheon-si Gyeonggi-do (KR)

(21) Appl. No.: 18/917,339

(22) Filed: Oct. 16, 2024

(30) Foreign Application Priority Data
Dec. 14, 2023 (KR) 10-2023-0182245
Jun. 27, 2024 (KR) 10-2024-0084608

(51) Int. Cl. H10B 80/00; H01L 23/00; H01L 25/00; H01L 25/065; H01L 25/18; H10B 43/27

(52) U.S. Cl. CPC H10B 80/00; H01L 24/08; H01L 24/80; H01L 25/0657; H01L 25/18; H01L 25/50; H10B 43/27; H01L 2224/08145; H01L 2224/80895; H01L 2224/80896; H01L 2924/1431; H01L 2924/14511

(57) ABSTRACT

A semiconductor device including a circuit structure which includes a page buffer. A first stack structure bonded over the circuit structure. A first source line disposed on the first stack structure. A first channel structure connected to the first source line by passing through the first stack structure is provided. A second stack structure bonded over the first stack structure and the first source line. A second source line disposed on the second stack structure. A second channel structure connected to the second source line by passing through the second stack structure is provided. A first bit through electrode connected to the second channel structure by passing through the first stack structure is provided. The first channel structure and the second channel structure connected to the page buffer.

### CROSS-REFERENCE TO RELATED APPLICATION

The present application claims priority under 35 U.S.C. § 119 (a) to Korean Patent Application Nos. 10-2023-0182245 and 10-2024-0084608 filed in the Korean Intellectual Property Office on Dec. 14, 2023 and Jun. 27, 2024, respectively, which applications are incorporated herein by reference in their entirety.

### BACKGROUND

### 1. Technical Field

Various embodiments of the disclosed technology generally relate to a semiconductor device, and more particularly, to a semiconductor device including a stack structure and a method of forming the stack structure.

### 2. Related Art

In response to the demand for high integration of a semiconductor device, a technology for sequentially stacking a plurality of wafers is being attempted. A plurality of memory wafers each having a stack structure may be sequentially stacked on a logic wafer. Increase in the number of memory wafers to be stacked may cause increase in the number of active/passive elements needed in a logic wafer. Signal transmission paths between a logic wafer and a plurality of memory wafers are becoming increasingly complicated.

### SUMMARY

In an embodiment, a semiconductor device may include a circuit structure which includes a page buffer. A first stack structure which is bonded over the circuit structure and includes a plurality of first insulating layers and a plurality of first horizontal electrodes alternately stacked may be provided. A first source line may be disposed on the first stack structure. A first channel structure which is connected to the first source line by passing through the first stack structure may be provided. A second stack structure which is bonded over the first stack structure and the first source line and includes a plurality of second insulating layers and a plurality of second horizontal electrodes alternately stacked may be provided. A second source line may be disposed on the second stack structure. A second channel structure which is connected to the second source line by passing through the second stack structure may be provided. A first bit through electrode which is connected to the second channel structure by passing through the first stack structure may be provided. The first channel structure may be connected to the page buffer. The second channel structure may be connected to the page buffer through the first bit through electrode.

In an embodiment, a semiconductor device may include a circuit structure which includes a decoder. A first stack structure which is bonded over the circuit structure and includes a plurality of first insulating layers and a plurality of first horizontal electrodes alternately stacked may be provided. The first stack structure may have a first cell area and a first connection area which is continuous to a side surface of the first cell area. A first source line may be disposed on the first stack structure. A first channel structure which is connected to the first source line by passing through the first stack structure and is disposed in the first cell area may be provided. A first contact plug which is disposed in the first connection area and is connected to one first horizontal electrode selected among the plurality of first horizontal electrodes may be provided. A second stack structure which is bonded over the first stack structure and the first source line and includes a plurality of second insulating layers and a plurality of second horizontal electrodes alternately stacked may be provided. The second stack structure may have a second cell area and a second connection area which is continuous to a side surface of the second cell area. A second source line may be disposed on the second stack structure. A second channel structure which is connected to the second source line by passing through the second stack structure and is disposed in the second cell area may be provided. A first slim through electrode which is connected to one second horizontal electrode selected among the plurality of second horizontal electrodes by passing through the first stack structure may be provided. The first contact plug and the first slim through electrode may be connected to the decoder.

In an embodiment, a semiconductor device may include a circuit structure which includes a page buffer. A first stack structure which is bonded over the circuit structure and includes a plurality of first insulating layers and a plurality of first horizontal electrodes alternately stacked may be provided. A first source line may be disposed on the first stack structure. A first channel structure which is connected to the first source line by passing through the first stack structure may be provided. A second stack structure which is bonded over the first stack structure and the first source line and includes a plurality of second insulating layers and a plurality of second horizontal electrodes alternately stacked may be provided. A second source line may be disposed on the second stack structure. A second channel structure which is connected to the second source line by passing through the second stack structure may be provided. A first source through electrode which is connected to the first source line and the second source line by passing through the second stack structure may be provided.

### BRIEF DESCRIPTION OF THE DRAWINGS

FIG. 1 is a cross-sectional view for explaining a semiconductor device based on an embodiment of the disclosed technology.

FIG. 2 is a partial view illustrating a part of FIG. 1.

FIGS. 3, 4, 5, 6, 7, and 8 are cross-sectional views for explaining semiconductor devices based on embodiments of the disclosed technology.

FIGS. 9, 10, 11, 12, 13, 14, 15, and 16 are cross-sectional views for explaining a method of forming a semiconductor device based on an embodiment of the disclosed technology.

FIGS. 17 and 18 are equivalent circuit diagrams for explaining semiconductor devices based on embodiments of the disclosed technology.

FIG. 19 is a cross-sectional view for explaining a semiconductor device based on an embodiment of the disclosed technology.

FIG. 20 is an equivalent circuit diagram for explaining a semiconductor device based on an embodiment of the disclosed technology.

FIGS. 21, 22, and 23 are cross-sectional views for explaining semiconductor devices based on embodiments of the disclosed technology.

FIG. 24 is an equivalent circuit diagram for explaining a semiconductor device based on an embodiment of the disclosed technology.

FIGS. 25 and 26 are cross-sectional views for explaining semiconductor devices based on embodiments of the disclosed technology.

### DETAILED DESCRIPTION

Various embodiments of the disclosed technology may be directed to providing a semiconductor device which is advantageous for high integration and has excellent electrical characteristics, and a method of forming the same.

According to various embodiments of the disclosed technology, it may be possible to implement a semiconductor device which is advantageous for high integration and has excellent electrical characteristics.

It will be understood that when an element or layer etc., is referred to as being “on,” “onto,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly onto,” “directly connected to” or “directly coupled to” another element or layer etc., there are no intervening elements or layers etc., present. Like numerals refer to like elements throughout. It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure.

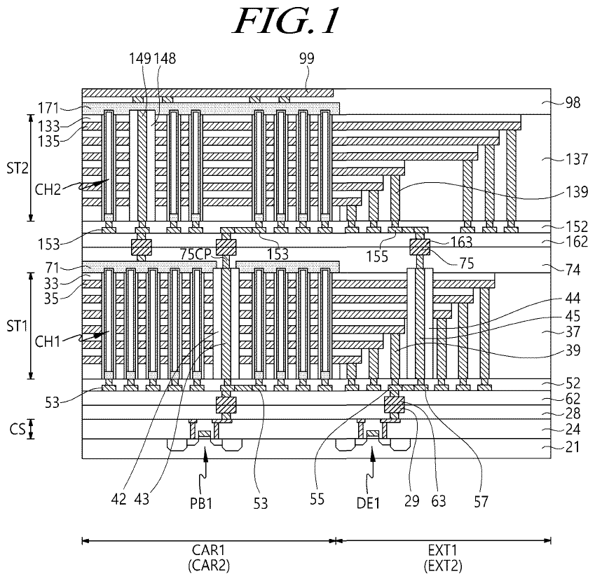

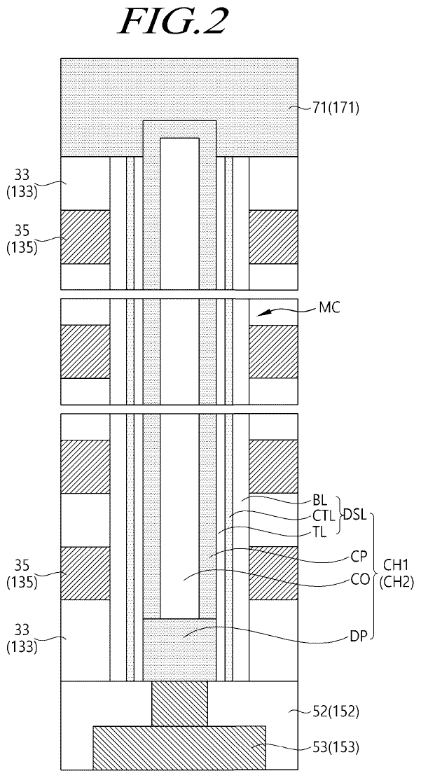

FIG. 1 is a cross-sectional view for explaining a semiconductor device based on an embodiment of the disclosed technology, and FIG. 2 is a partial view illustrating a part of FIG. 1.

Referring to FIG. 1, the semiconductor device based on the embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a first slim through electrode 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a bit contact plug 75CP, a second stack structure ST2, a plurality of second channel structures CH2, an upper insulating layer 98, a source interconnection 99, a second buried insulating layer 137, a plurality of second contact plugs 139, a first source insulating block 148, a first source through electrode 149, a second interlayer insulating layer 152, a plurality of second interconnections 153 and 155, a fourth insulating bonding layer 162, plurality of fourth bonding pads 163, and a second source line 171.

The circuit structure CS may be disposed on the first substrate 21. The circuit structure CS may include a first page buffer PB1, a first decoder DE1 and a circuit insulating layer 24. The circuit insulating layer 24 may cover the first page buffer PB1 and the first decoder DE1. The first insulating bonding layer 28 may be disposed on the circuit structure CS. The plurality of first bonding pads 29 may be disposed in the first insulating bonding layer 28. Each of the plurality of first bonding pads 29 may be connected to a corresponding one of the first page buffer PB1 and the first decoder DE1. One surfaces (e.g., upper surfaces) of the first insulating bonding layer 28 and the plurality of first bonding pads 29 may form substantially the same plane.

The first stack structure ST1 may include a first cell area CAR1 and a first connection area EXT1. The first connection area EXT1 may be continuous to the side surface of the first cell area CAR1. The first stack structure ST1 may include a plurality of first insulating layers 33 and a plurality of first horizontal electrodes 35 which are alternately stacked. In the first connection area EXT1, the plurality of first insulating layers 33 and the plurality of first horizontal electrodes 35 may have step shapes. The first buried insulating layer 37 may be disposed on the plurality of first insulating layers 33 and the plurality of first horizontal electrodes 35 which form the step shapes. Each of the plurality of first contact plugs 39 may pass through the first buried insulating layer 37 and contact a corresponding one among the plurality of first horizontal electrodes 35.

The first source line 71 may be disposed on the first stack structure ST1. Each of the plurality of first channel structures CH1 may extend into the first source line 71 by vertically passing through the first stack structure ST1. The plurality of first channel structures CH1 may be disposed in the first cell area CAR1.

The first bit insulating block 42 and the first bit through electrode 43 may pass through the first stack structure ST1. The first bit through electrode 43 may be disposed in the first bit insulating block 42. The first bit insulating block 42 may serve to insulate the first bit through electrode 43 and the plurality of first horizontal electrodes 35 from each other. The side surface of the first bit insulating block 42 may contact the plurality of first horizontal electrodes 35. In an embodiment, the first bit insulating block 42 and the first bit through electrode 43 may be disposed in the first cell area CAR1. The first bit insulating block 42 and the first bit through electrode 43 may be disposed adjacent to the plurality of first channel structures CH1. The first bit insulating block 42 and the first bit through electrode 43 may be disposed between the plurality of first channel structures CH1.

The first slim insulating block 44 and the first slim through electrode 45 may pass through the first buried insulating layer 37 and the first stack structure ST1. The first slim through electrode 45 may be disposed in the first slim insulating block 44. The first slim insulating block 44 may serve to insulate the first slim through electrode 45 and the plurality of first horizontal electrodes 35 from each other. The side surface of the first slim insulating block 44 may contact the plurality of first horizontal electrodes 35. In an embodiment, the first slim insulating block 44 and the first slim through electrode 45 may be disposed in the first connection area EXT1. The first slim insulating block 44 and the first slim through electrode 45 may be disposed adjacent to the plurality of first contact plugs 39. The first slim insulating block 44 and the first slim through electrode 45 may be disposed between the plurality of first contact plugs 39.

The first interlayer insulating layer 52 may be disposed on one surfaces (e.g., lower surfaces) of the first stack structure ST1, the plurality of first channel structures CH1, the first buried insulating layer 37, the plurality of first contact plugs 39, the first bit insulating block 42, the first bit through electrode 43, the first slim insulating block 44 and the first slim through electrode 45. The first interlayer insulating layer 52 may be disposed between the first insulating bonding layer 28 and the first stack structure ST1. The plurality of first interconnections 53, 55 and 57 may be disposed in the first interlayer insulating layer 52. The plurality of first interconnections 53, 55 and 57 may include a plurality of first bit lines 53, a plurality of first word interconnections 55 and a second word interconnection 57. The plurality of first bit lines 53 may be connected to the plurality of first channel structures CH1. The plurality of first word interconnections 55 may be connected to the plurality of first contact plugs 39. The second word interconnection 57 may be connected to the first slim through electrode 45.

The second insulating bonding layer 62 may be disposed on the first interlayer insulating layer 52 and the plurality of first interconnections 53, 55 and 57. The second insulating bonding layer 62 may be disposed between the first insulating bonding layer 28 and the first interlayer insulating layer 52. The plurality of second bonding pads 63 may be disposed in the second insulating bonding layer 62. The plurality of second bonding pads 63 may be connected to the plurality of first interconnections 53, 55 and 57. One surfaces (e.g., lower surfaces) of the second insulating bonding layer 62 and the plurality of second bonding pads 63 may form substantially the same plane.

The first stack structure ST1 may be bonded onto the circuit structure CS. In an embodiment, the second insulating bonding layer 62 may be bonded onto the first insulating bonding layer 28, and the plurality of second bonding pads 63 may be bonded onto the plurality of first bonding pads 29. The plurality of second bonding pads 63 may contact the plurality of first bonding pads 29.

The third insulating bonding layer 74 may be disposed on the first source line 71 and the first stack structure ST1. The plurality of third bonding pads 75 may be disposed in the third insulating bonding layer 74. One surfaces (e.g., upper surfaces) of the third insulating bonding layer 74 and the plurality of third bonding pads 75 may form substantially the same plane. The third insulating bonding layer 74 may contact the first bit insulating block 42 by passing through the first source line 71. The bit contact plug 75CP may be disposed in the third insulating bonding layer 74. The bit contact plug 75CP may pass through the third insulating bonding layer 74 and the first source line 71, and may be disposed between one selected among the plurality of third bonding pads 75 and the first bit through electrode 43. The bit contact plug 75CP may contact one selected among the plurality of third bonding pads 75, and may contact the first bit through electrode 43. Another one selected among the plurality of third bonding pads 75 may be connected to the first source line 71, and still another one selected among the plurality of third bonding pads 75 may be connected to the first slim through electrode 45.

In an embodiment, the uppermost end of each of the first bit insulating block 42, the first bit through electrode 43, the first slim insulating block 44 and the first slim through electrode 45 may protrude to a level higher than the adjacent upper surface of the first stack structure ST1. The first bit insulating block 42 and the first bit through electrode 43 may extend into the first source line 71. The first slim insulating block 44 and the first slim through electrode 45 may extend into the third insulating bonding layer 74. The interface between the bit contact plug 75CP and the first bit through electrode 43 may be disposed between the upper surface and the lower surface of the first source line 71.

The second stack structure ST2 may include a second cell area CAR2 and a second connection area EXT2. The second connection area EXT2 may be continuous to the side surface of the second cell area CAR2. The second stack structure ST2 may include a plurality of second insulating layers 133 and a plurality of second horizontal electrodes 135 which are alternately stacked. In the second connection area EXT2, the plurality of second insulating layers 133 and the plurality of second horizontal electrodes 135 may have step shapes. The second buried insulating layer 137 may be disposed on the plurality of second insulating layers 133 and the plurality of second horizontal electrodes 135 which form the step shapes. Each of the plurality of second contact plugs 139 may pass through the second buried insulating layer 137 and contact a corresponding one among the plurality of second horizontal electrodes 135.

The second source line 171 may be disposed on the second stack structure ST2. Each of the plurality of second channel structures CH2 may extend into the second source line 171 by vertically passing through the second stack structure ST2. The plurality of second channel structures CH2 may be disposed in the second cell area CAR2.

The first source insulating block 148 and the first source through electrode 149 may extend into the second source line 171 by vertically passing through the second stack structure ST2. The first source through electrode 149 may be disposed in the first source insulating block 148. The first source insulating block 148 may serve to insulate the first source through electrode 149 and the plurality of second horizontal electrodes 135 from each other. The side surface of the first source insulating block 148 may contact the plurality of second horizontal electrodes 135. In an embodiment, the first source insulating block 148 and the first source through electrode 149 may be disposed in the second cell area CAR2. The first source insulating block 148 and the first source through electrode 149 may be disposed adjacent to the plurality of second channel structures CH2. The first source insulating block 148 and the first source through electrode 149 may be disposed between the plurality of second channel structures CH2. The uppermost end of each of the first source insulating block 148 and the first source through electrode 149 may be disposed at a level higher than the lowermost surface of the second source line 171. For example, as shown in FIG. 1, the uppermost end of each of the first source insulating block 148 and the first source through electrode 149 may be disposed at a level higher than the lowermost surface of the second source line 171. The first source through electrode 149 may directly contact the second source line 171.

The second interlayer insulating layer 152 may be disposed on one surfaces (e.g., lower surfaces) of the second stack structure ST2, the plurality of second channel structures CH2, the second buried insulating layer 137, the plurality of second contact plugs 139, the first source insulating block 148 and the first source through electrode 149. The second interlayer insulating layer 152 may be disposed between the third insulating bonding layer 74 and the second stack structure ST2. The plurality of second interconnections 153 and 155 may be disposed in the second interlayer insulating layer 152. The plurality of second interconnections 153 and 155 may include a plurality of second bit lines 153 and a plurality of third word interconnections 155. The plurality of second bit lines 153 may be connected to the plurality of second channel structures CH2. The plurality of third word interconnections 155 may be connected to the plurality of second contact plugs 139.

The fourth insulating bonding layer 162 may be disposed on the second interlayer insulating layer 152 and the plurality of second interconnections 153 and 155. The fourth insulating bonding layer 162 may be disposed between the third insulating bonding layer 74 and the second interlayer insulating layer 152. The plurality of fourth bonding pads 163 may be disposed in the fourth insulating bonding layer 162. The plurality of fourth bonding pads 163 may be connected to the plurality of second interconnections 153 and 155. One surfaces (e.g., lower surfaces) of the fourth insulating bonding layer 162 and the plurality of fourth bonding pads 163 may form substantially the same plane.

The second stack structure ST2 may be bonded onto the first stack structure ST1 and the first source line 71. In an embodiment, the fourth insulating bonding layer 162 may be bonded onto the third insulating bonding layer 74, and the plurality of fourth bonding pads 163 may be bonded onto the plurality of third bonding pads 75. The plurality of fourth bonding pads 163 may contact the plurality of third bonding pads 75.

The upper insulating layer 98 may be disposed on the second source line 171 and the second stack structure ST2. The source interconnection 99 may be disposed in the upper insulating layer 98. The source interconnection 99 may be connected to the second source line 171. In an embodiment, the source interconnection 99 may serve to reduce the interconnection resistance of the second source line 171.

Referring to FIG. 2, the first channel structure CH1 may include a core layer CO, a channel pattern CP, an information storage pattern DSL and a drain pad DP. The channel pattern CP may surround the side surface and the upper surface of the core layer CO. The information storage pattern DSL may surround the side surface of the channel pattern CP. The drain pad DP may be disposed under the core layer CO and the channel pattern CP. The drain pad DP may directly contact the channel pattern CP. The drain pad DP may be connected to the first bit line 53. The second channel structure CH2 may include a similar configuration to the first channel structure CH1.

The first channel structure CH1 may extend into the first source line 71 by vertically passing through the plurality of first insulating layers 33 and the plurality of first horizontal electrodes 35 which are alternately and repeatedly stacked. The core layer CO and the channel pattern CP may extend into the first source line 71. The uppermost end of the channel pattern CP may be disposed at a level higher than the lowermost surface of the first source line 71. For example, the uppermost end of the channel pattern CP may be disposed at a level higher than the lowermost surface of the first source line 71 as shown in FIG. 2. The channel pattern CP may directly contact the first source line 71. In an embodiment, the first source line 71 may directly contact the upper surface and the side surface of the channel pattern CP. The information storage pattern DSL may be disposed between the channel pattern CP and the plurality of first horizontal electrodes 35 and between the channel pattern CP and the plurality of first insulating layers 33. The uppermost end of the information storage pattern DSL may be disposed at a level lower than the uppermost end of the channel pattern CP.

The information storage pattern DSL may include a tunnel layer TL, a charge trap layer CTL and a blocking layer BL. The charge trap layer CTL may be disposed between the tunnel layer TL and the blocking layer BL. The tunnel layer TL may be disposed between the channel pattern CP and the charge trap layer CTL. The blocking layer BL may be disposed between the charge trap layer CTL and the plurality of first horizontal electrodes 35 and between the charge trap layer CTL and the plurality of first insulating layers 33. The uppermost end of each of the tunnel layer TL, the charge trap layer CTL and the blocking layer BL may directly contact the first source line 71. In an embodiment, the equivalent oxide thickness (EOT) of the blocking layer BL may be thicker than the equivalent oxide thickness (EOT) of the tunnel layer TL. The thickness of each of the blocking layer BL and the tunnel layer TL may correspond to the horizontal width shown in FIG. 2.

The first source line 71 may correspond to a common source line. The plurality of first horizontal electrodes 35 may include a plurality of word lines, a plurality of select lines, and at least one GIDL (gate induced drain leakage) control line. A plurality of memory cells MC may be formed at intersections of the first channel structure CH1 and a plurality of word lines.

In an embodiment, among the plurality of first horizontal electrodes 35, at least one adjacent to the first source line 71 may correspond to a source select line. Among the plurality of first horizontal electrodes 35, at least one adjacent to the drain pad DP may correspond to a drain select line. Among the plurality of first horizontal electrodes 35, one adjacent to the first source line 71 and/or one adjacent to the drain pad DP may correspond to a GIDL control line. A plurality of word lines may be disposed between at least one drain select line and at least one source select line among the plurality of first horizontal electrodes 35.

Referring to FIGS. 1 and 2 again, in an embodiment, the second source line 171 may be connected to the first source line 71 through the first source through electrode 149, a corresponding one among the plurality of fourth bonding pads 163 and a corresponding one among the plurality of third bonding pads 75. The first source line 71 and the second source line 171 may be controlled to an on or off state at the same time or at least partially overlapping intervals of time. The upper surface and the side surface of the channel pattern CP may directly contact the first source line 71 or the second source line 171. In an embodiment, the current driving capability between the first source line 71 and the plurality of first channel structures CH1 may be increased, and the current driving capability between the second source line 171 and the plurality of second channel structures CH2 may be increased.

In an embodiment, one selected among the plurality of first channel structures CH1 and one selected among the plurality of second channel structures CH2 may be connected in common to the first page buffer PB1. For example, one selected among the plurality of first channel structures CH1 may be connected to the first page buffer PB1 through a corresponding one among the plurality of first bit lines 53, a corresponding one among the plurality of second bonding pads 63 and a corresponding one among the plurality of first bonding pads 29, and one selected among the plurality of second channel structures CH2 may be connected to the first page buffer PB1 through a corresponding one among the plurality of second bit lines 153, a corresponding one among the plurality of fourth bonding pads 163, a corresponding one among the plurality of third bonding pads 75, the bit contact plug 75CP, the first bit through electrode 43, a corresponding one among the plurality of second bonding pads 63 and a corresponding one among the plurality of first bonding pads 29.

In an embodiment, one selected among the plurality of first horizontal electrodes 35 and one selected among the plurality of second horizontal electrodes 135 may be connected in common to the first decoder DE1. For example, one selected among the plurality of first horizontal electrodes 35 may be connected to the first decoder DE1 through a corresponding one among the plurality of first contact plugs 39, a corresponding one among the plurality of first word interconnections 55, a corresponding one among the plurality of second bonding pads 63 and a corresponding one among the plurality of first bonding pads 29, and one selected among the plurality of second horizontal electrodes 135 may be connected to the first decoder DE1 through a corresponding one among the plurality of second contact plugs 139, a corresponding one among the plurality of third word interconnections 155, a corresponding one among the plurality of fourth bonding pads 163, a corresponding one among the plurality of third bonding pads 75, the first slim through electrode 45, the second word interconnection 57, a corresponding one among the plurality of first word interconnections 55, a corresponding one among the plurality of second bonding pads 63 and a corresponding one among the plurality of first bonding pads 29.

In an embodiment, each of the first page buffer PB1 and the first decoder DE1 may include one or a plurality of transistors. In an embodiment, each of the first page buffer PB1 and the first decoder DE1 may include a pass transistor or a switching transistor. In an embodiment, one selected among the plurality of first channel structures CH1 and one selected among the plurality of second channel structures CH2 may be connected to the source/drain of the pass transistor or the switching transistor included in the first page buffer PB1. In an embodiment, one selected among the plurality of first horizontal electrodes 35 and one selected among the plurality of second horizontal electrodes 135 may be connected to the source/drain of the pass transistor or the switching transistor included in the first decoder DE1.

According to an embodiment of the disclosed technology, the number of memory cells MC connected to the first page buffer PB1 and the first decoder DE1 may be increased. In an embodiment, it may be possible to implement a semiconductor device which is advantageous for increasing memory capacity while suppressing increase in area.

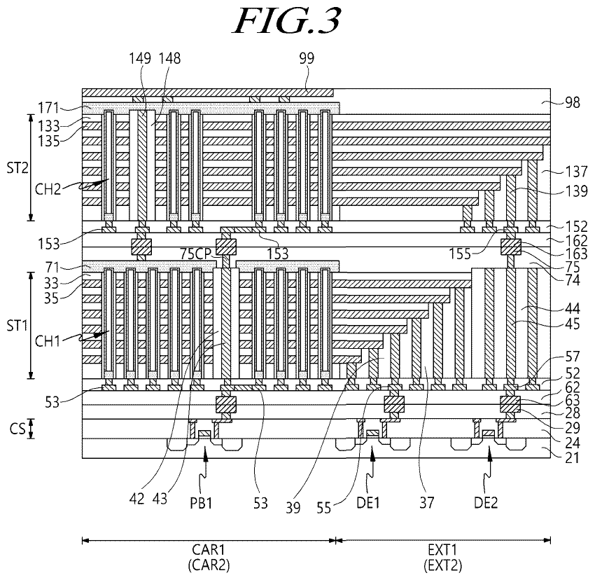

FIGS. 3 to 8 are cross-sectional views for explaining semiconductor devices based on embodiments of the disclosed technology.

Referring to FIG. 3, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a plurality of first slim through electrodes 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a bit contact plug 75CP, a second stack structure ST2, a plurality of second channel structures CH2, an upper insulating layer 98, a source interconnection 99, a second buried insulating layer 137, a plurality of second contact plugs 139, a first source insulating block 148, a first source through electrode 149, a second interlayer insulating layer 152, a plurality of second interconnections 153 and 155, a fourth insulating bonding layer 162, a plurality of fourth bonding pads 163, and a second source line 171.

The circuit structure CS may include a first page buffer PB1, a first decoder DE1, a second decoder DE2 and a circuit insulating layer 24. Each of the plurality of first bonding pads 29 may be connected to a corresponding one among the first page buffer PB1, the first decoder DE1 and the second decoder DE2.

The first slim insulating block 44 and the plurality of first slim through electrodes 45 may pass through the first buried insulating layer 37 and the first stack structure ST1. In an embodiment, the first slim insulating block 44 and the plurality of first slim through electrodes 45 may be disposed in a first connection area EXT1. The plurality of first interconnections 53, 55 and 57 may include a plurality of first bit lines 53, a plurality of first word interconnections 55 and a plurality of second word interconnections 57. The plurality of second word interconnections 57 may be connected to the plurality of first slim through electrodes 45. One selected among the plurality of third bonding pads 75 may be connected to a corresponding one among the plurality of first slim through electrodes 45.

In an embodiment, one selected among the plurality of first horizontal electrodes 35 may be connected to the first decoder DE1, and one selected among the plurality of second horizontal electrodes 135 may be connected to the second decoder DE2. For example, one selected among the plurality of first horizontal electrodes 35 may be connected to the first decoder DE1 through a corresponding one among the plurality of first contact plugs 39, a corresponding one among the plurality of first word interconnections 55, a corresponding one among the plurality of second bonding pads 63 and a corresponding one among the plurality of first bonding pads 29. One selected among the plurality of second horizontal electrodes 135 may be connected to the second decoder DE2 through a corresponding one among the plurality of second contact plugs 139, a corresponding one among the plurality of third word interconnections 155, a corresponding one among the plurality of fourth bonding pads 163, a corresponding one among the plurality of third bonding pads 75, a corresponding one among the plurality of first slim through electrodes 45, a corresponding one among the plurality of second word interconnections 57, a corresponding one among the plurality of second bonding pads 63 and a corresponding one among the plurality of first bonding pads 29.

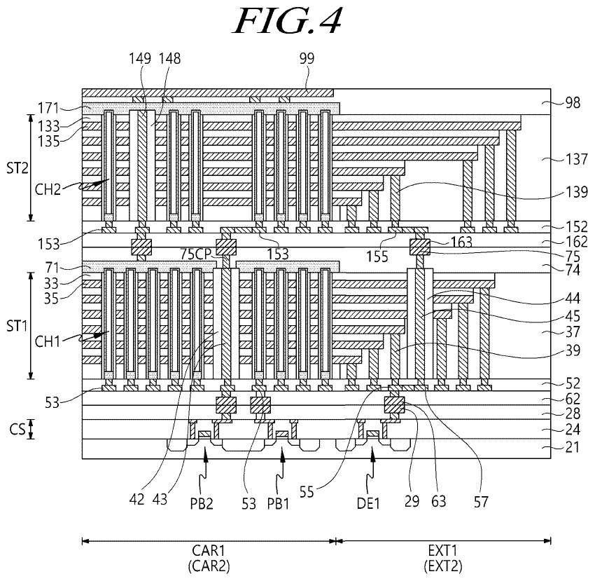

Referring to FIG. 4, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a plurality of first slim through electrodes 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a bit contact plug 75CP, a second stack structure ST2, a plurality of second channel structures CH2, an upper insulating layer 98, a source interconnection 99, a second buried insulating layer 137, a plurality of second contact plugs 139, a first source insulating block 148, a first source through electrode 149, a second interlayer insulating layer 152, a plurality of second interconnections 153 and 155, a fourth insulating bonding layer 162, plurality of fourth bonding pads 163, and a second source line 171.

The circuit structure CS may include a first page buffer PB1, a second page buffer PB2, a first decoder DE1, and a circuit insulating layer 24. Each of the plurality of first bonding pads 29 may be connected to a corresponding one among the first page buffer PB1, the second page buffer PB2 and the first decoder DE1.

In an embodiment, one selected among the plurality of first channel structures CH1 may be connected to the first page buffer PB1, and one selected among the plurality of second channel structures CH2 may be connected to the second page buffer PB2. For example, one selected among the plurality of first channel structures CH1 may be connected to the first page buffer PB1 through a corresponding one among the plurality of first bit lines 53, a corresponding one among the plurality of second bonding pads 63 and a corresponding one among the plurality of first bonding pads 29. One selected among the plurality of second channel structures CH2 may be connected to the second page buffer PB2 through a corresponding one among the plurality of second bit lines 153, a corresponding one among the plurality of fourth bonding pads 163, a corresponding one among the plurality of third bonding pads 75, the bit contact plug 75CP, the first bit through electrode 43, a corresponding one among the plurality of second bonding pads 63 and a corresponding one among the plurality of first bonding pads 29.

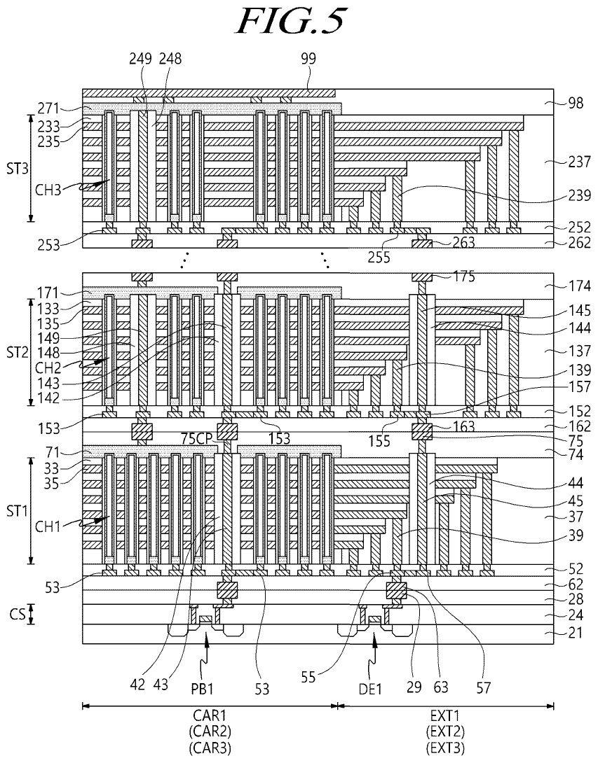

Referring to FIG. 5, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a plurality of first slim through electrodes 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a bit contact plug 75CP, a second stack structure ST2, a plurality of second channel structures CH2, an upper insulating layer 98, a source interconnection 99, a second buried insulating layer 137, a plurality of second contact plugs 139, a second bit insulating block 142, a second bit through electrode 143, a second slim insulating block 144, a second slim through electrode 145, a first source insulating block 148, a first source through electrode 149, a second interlayer insulating layer 152, a plurality of second interconnections 153, 155 and 157, a fourth insulating bonding layer 162, a plurality of fourth bonding pads 163, a second source line 171, a fifth insulating bonding layer 174, a plurality of fifth bonding pads 175, a third stack structure ST3, a third buried insulating layer 237, a plurality of third contact plugs 239, a plurality of third channel structures CH3, a second source insulating block 248, a second source through electrode 249, a third interlayer insulating layer 252, a plurality of third interconnections 253 and 255, a sixth insulating bonding layer 262, a plurality of sixth bonding pads 263, and a third source line 271.

The circuit structure CS may include a first page buffer PB1, a first decoder DE1 and a circuit insulating layer 24. Each of the plurality of first bonding pads 29 may be connected to a corresponding one of the first page buffer PB1 and the first decoder DE1.

The second bit insulating block 142 and the second bit through electrode 143 may pass through the second stack structure ST2. The second bit through electrode 143 may be disposed in the second bit insulating block 142. The second bit insulating block 142 may serve to insulate the second bit through electrode 143 and the plurality of second horizontal electrodes 135 from each other. The side surface of the second bit insulating block 142 may contact the plurality of second horizontal electrodes 135. In an embodiment, the second bit insulating block 142 and the second bit through electrode 143 may be disposed in a second cell area CAR2. The second bit insulating block 142 and the second bit through electrode 143 may be disposed adjacent to the plurality of second channel structures CH2. The second bit insulating block 142 and the second bit through electrode 143 may be disposed between the plurality of second channel structures CH2.

The second slim insulating block 144 and the second slim through electrode 145 may pass through the second buried insulating layer 137 and the second stack structure ST2. The second slim through electrode 145 may be disposed in the second slim insulating block 144. The second slim insulating block 144 may serve to insulate the second slim through electrode 145 and the plurality of second horizontal electrodes 135 from each other. The side surface of the second slim insulating block 144 may contact the plurality of second horizontal electrodes 135. In an embodiment, the second slim insulating block 144 and the second slim through electrode 145 may be disposed in a second connection area EXT2. The second slim insulating block 144 and the second slim through electrode 145 may be disposed adjacent to the plurality of second contact plugs 139. The second slim insulating block 144 and the second slim through electrode 145 may be disposed between the plurality of second contact plugs 139.

The second interlayer insulating layer 152 may be disposed on one surfaces (e.g., lower surfaces) of the second stack structure ST2, the plurality of second channel structures CH2, the second buried insulating layer 137, the plurality of second contact plugs 139, the second bit insulating block 142, the second bit through electrode 143, the second slim insulating block 144, the second slim through electrode 145, the first source insulating block 148 and the first source through electrode 149. The second interlayer insulating layer 152 may be disposed between the third insulating bonding layer 74 and the second stack structure ST2. The plurality of second interconnections 153, 155 and 157 may be disposed in the second interlayer insulating layer 152. The plurality of second interconnections 153, 155 and 157 may include a plurality of second bit lines 153, a plurality of third word interconnections 155 and a fourth word interconnection 157. The plurality of second bit lines 153 may be connected to the plurality of second channel structures CH2. The plurality of third word interconnections 155 may be connected to the plurality of second contact plugs 139. The fourth word interconnection 157 may be connected to the second slim through electrode 145. The plurality of fourth bonding pads 163 may be connected to the plurality of second interconnections 153, 155 and 157.

The fifth insulating bonding layer 174 may be disposed on the second source line 171 and the second stack structure ST2. The plurality of fifth bonding pads 175 may be disposed in the fifth insulating bonding layer 174. One surfaces (e.g., upper surfaces) of the fifth insulating bonding layer 174 and the plurality of fifth bonding pads 175 may form substantially the same plane. The fifth insulating bonding layer 174 may contact the second bit insulating block 142 by passing through the second source line 171. One selected among the plurality of fifth bonding pads 175 may be connected to the second bit through electrode 143. Another one selected among the plurality of fifth bonding pads 175 may be connected to the second source line 171, and still another one selected among the plurality of fifth bonding pads 175 may be connected to the second slim through electrode 145.

In an embodiment, the uppermost end of each of the second bit insulating block 142, the second bit through electrode 143, the second slim insulating block 144, the second slim through electrode 145, the first source insulating block 148 and the first source through electrodes 149 may protrude to a level higher than the adjacent upper surface of the second stack structure ST2.

The third stack structure ST3 may include a third cell area CAR3 and a third connection area EXT3. The third stack structure ST3 may include a plurality of third insulating layers 233 and a plurality of third horizontal electrodes 235 which are alternately stacked. The plurality of third interconnections 253 and 255 may include a plurality of third bit lines 253 and a plurality of fifth word interconnections 255.

The third stack structure ST3, the third buried insulating layer 237, the plurality of third contact plugs 239, the plurality of third channel structures CH3, the second source insulating block 248, the second source through electrode 249, the third interlayer insulating layer 252, the plurality of third interconnections 253 and 255, the sixth insulating bonding layer 262, the plurality of sixth bonding pads 263 and the third source line 271 may include configurations similar to the second stack structure ST2, the plurality of second channel structures CH2, the second buried insulating layer 137, the plurality of second contact plugs 139, the first source Insulating block 148, the first source through electrode 149, the second interlayer insulating layer 152, the plurality of second interconnections 153 and 155, the fourth insulating bonding layer 162, the plurality of fourth bonding pads 163 and the second source line 171 described above with reference to FIG. 1.

The third stack structure ST3 may be bonded onto the second stack structure ST2 and the second source line 171. In an embodiment, the sixth insulating bonding layer 262 may be bonded onto the fifth insulating bonding layer 174, and the plurality of sixth bonding pads 263 may be bonded onto the plurality of fifth bonding pads 175.

The upper insulating layer 98 may be disposed on the third source line 271 and the third stack structure ST3. The source interconnection 99 may be disposed in the upper insulating layer 98. The source interconnection 99 may be connected to the third source line 271. In an embodiment, the source interconnection 99 may serve to reduce the interconnection resistance of the third source line 271.

In an embodiment, the third stack structure ST3 may correspond to an uppermost stack structure. One another stack structure or a plurality of other stack structures may be additionally stacked between the second stack structure ST2 and the uppermost stack structure (e.g., the third stack structure ST3).

In an embodiment, the third source line 271 may be connected to the second source line 171 through the second source through electrode 249, a corresponding one among the plurality of sixth bonding pads 263 and a corresponding one among the plurality of fifth bonding pads 175. The second source line 171 may be connected to the first source line 71 through the first source through electrode 149, a corresponding one among the plurality of fourth bonding pads 163 and a corresponding one among the plurality of third bonding pads 75. The first source line 71, the second source line 171 and the third source line 271 may be controlled to an on or off at the same time or at least partially overlapping intervals of time.

In an embodiment, one selected among the plurality of first channel structures CH1, one selected among the plurality of second channel structures CH2 and one selected among the plurality of third channel structures CH3 may be connected in common to the first page buffer PB1. For example, one selected among the plurality of first channel structures CH1 may be connected to the first page buffer PB1 through a corresponding one among the plurality of first bit lines 53, a corresponding one among the plurality of second bonding pads 63 and a corresponding one among the plurality of first bonding pads 29. One selected among the plurality of second channel structures CH2 may be connected to the first page buffer PB1 through a corresponding one among the plurality of second bit lines 153, a corresponding one among the plurality of fourth bonding pads 163, a corresponding one among the plurality of third bonding pads 75, the bit contact plug 75CP, the first bit through electrode 43, a corresponding one among the plurality of second bonding pads 63 and a corresponding one among the plurality of first bonding pads 29. One selected among the plurality of third channel structures CH3 may be connected to the first page buffer PB1 through a corresponding one among the plurality of third bit lines 253, a corresponding one among the plurality of sixth bonding pads 263, a corresponding one among the plurality of fifth bonding pads 175, the second bit through electrode 143, a corresponding one among the plurality of fourth bonding pads 163, a corresponding one among the plurality of third bonding pads 75, the bit contact plug 75CP, the first bit through electrode 43, a corresponding one among the plurality of second bonding pads 63 and a corresponding one among the plurality of first bonding pads 29.

In an embodiment, one selected among the plurality of first horizontal electrodes 35, one selected among the plurality of second horizontal electrodes 135 and one selected among the plurality of third horizontal electrodes 235 may be connected in common to the first decoder DE1. For example, one selected among the plurality of first horizontal electrodes 35 may be connected to the first decoder DE1 through a corresponding one among the plurality of first contact plugs 39, a corresponding one among the plurality of first word interconnections 55, a corresponding one among the plurality of second bonding pads 63 and a corresponding one among the plurality of first bonding pads 29. One selected among the plurality of second horizontal electrodes 135 may be connected to the first decoder DE1 through a corresponding one among the plurality of second contact plugs 139, a corresponding one among the plurality of third word interconnections 155, the fourth word interconnection 157, a corresponding one among the plurality of fourth bonding pads 163, a corresponding one among the plurality of third bonding pads 75, the first slim through electrode 45, the second word interconnection 57, a corresponding one among the plurality of first word interconnections 55, a corresponding one among the plurality of second bonding pads 63 and a corresponding one among the plurality of first bonding pads 29. One selected among the plurality of third horizontal electrodes 235 may be connected to the first decoder DE1 through a corresponding one among the plurality of third contact plugs 239, a corresponding one among the plurality of fifth word interconnections 255, a corresponding one among the plurality of sixth bonding pads 263, a corresponding one among the plurality of fifth bonding pads 175, the second slim through electrode 145, the fourth word interconnection 157, a corresponding one among the plurality of fourth bonding pads 163, a corresponding one among the plurality of third bonding pads 75, the first slim through electrode 45, the second word interconnection 57, a corresponding one among the plurality of first word interconnections 55, a corresponding one among the plurality of second bonding pads 63 and a corresponding one among the plurality of first bonding pads 29.

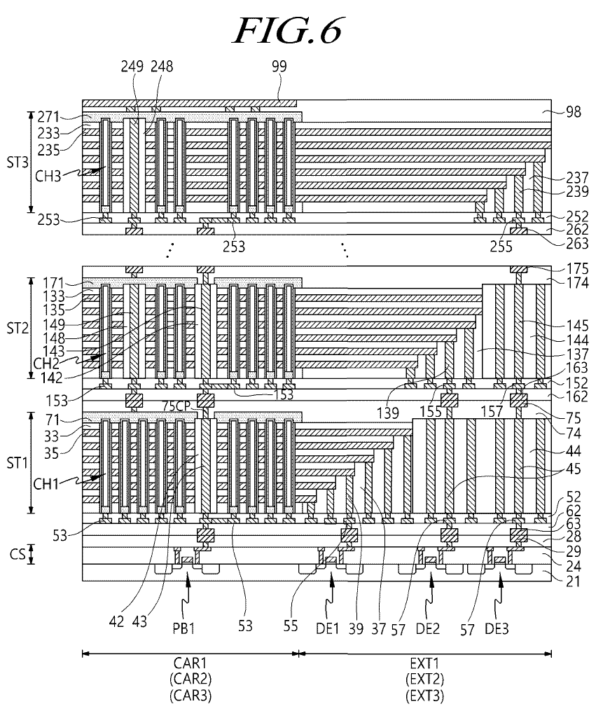

Referring to FIG. 6, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a plurality of first slim through electrodes 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a bit contact plug 75CP, a second stack structure ST2, a plurality of second channel structures CH2, an upper insulating layer 98, a source interconnection 99, a second buried insulating layer 137, a plurality of second contact plugs 139, a second bit insulating block 142, a second bit through electrode 143, a second slim insulating block 144, a plurality of second slim through electrodes 145, a first source insulating block 148, a first source through electrode 149, a second interlayer insulating layer 152, a plurality of second interconnections 153, 155 and 157, a fourth insulating bonding layer 162, a plurality of fourth bonding pads 163, a second source line 171, a fifth insulating bonding layer 174, a plurality of fifth bonding pads 175, a third stack structure ST3, a third buried insulating layer 237, a plurality of third contact plugs 239, a plurality of third channel structures CH3, a second source insulating block 248, a second source through electrode 249, a third interlayer insulating layer 252, a plurality of third interconnections 253 and 255, a sixth insulating bonding layer 262, a plurality of sixth bonding pads 263, and a third source line 271.

The circuit structure CS may include a first page buffer PB1, a first decoder DE1, a second decoder DE2, a third decoder DE3 and a circuit insulating layer 24. Each of the plurality of first bonding pads 29 may be connected to a corresponding one among the first page buffer PB1, the first decoder DE1, the second decoder DE2 and the third decoder DE3.

The second slim insulating block 144 and the plurality of second slim through electrodes 145 may pass through the second buried insulating layer 137 and the second stack structure ST2. In an embodiment, the second slim insulating block 144 and the plurality of second slim through electrodes 145 may be disposed in a second connection area EXT2. The plurality of second interconnections 153, 155 and 157 may include a plurality of second bit lines 153, a plurality of third word interconnections 155 and a plurality of fourth word interconnections 157. The plurality of fourth word interconnections 157 may be connected to the plurality of second slim through electrodes 145.

In an embodiment, one selected among the plurality of first horizontal electrodes 35 may be connected to the first decoder DE1, one selected among the plurality of second horizontal electrodes 135 may be connected to the second decoder DE2, and one selected among the plurality of third horizontal electrodes 235 may be connected to the third decoder DE3. For example, one selected among the plurality of first horizontal electrodes 35 may be connected to the first decoder DE1 through a corresponding one among the plurality of first contact plugs 39, a corresponding one among the plurality of first word interconnections 55, a corresponding one among the plurality of second bonding pads 63 and a corresponding one among the plurality of first bonding pads 29. One selected among the plurality of second horizontal electrodes 135 may be connected to the second decoder DE2 through a corresponding one among the plurality of second contact plugs 139, a corresponding one among the plurality of third word interconnections 155, a corresponding one among the plurality of fourth bonding pads 163, a corresponding one among the plurality of third bonding pads 75, a corresponding one among the plurality of first slim through electrodes 45, a corresponding one among the plurality of second word interconnections 57, a corresponding one among the plurality of second bonding pads 63 and a corresponding one among the plurality of first bonding pads 29.

One selected among the plurality of third horizontal electrodes 235 may be connected to the third decoder DE3 through a corresponding one among the plurality of third contact plugs 239, a corresponding one among the plurality of fifth word interconnections 255, a corresponding one among the plurality of sixth bonding pads 263, a corresponding one among the plurality of fifth bonding pads 175, a corresponding one among the plurality of second slim through electrodes 145, a corresponding one among the plurality of fourth word interconnections 157, a corresponding one among the plurality of fourth bonding pads 163, a corresponding one among the plurality of third bonding pads 75, a corresponding one among the plurality of first slim through electrodes 45, a corresponding one among the plurality of second word interconnections 57, a corresponding one among the plurality of second bonding pads 63 and a corresponding one among the plurality of first bonding pads 29.

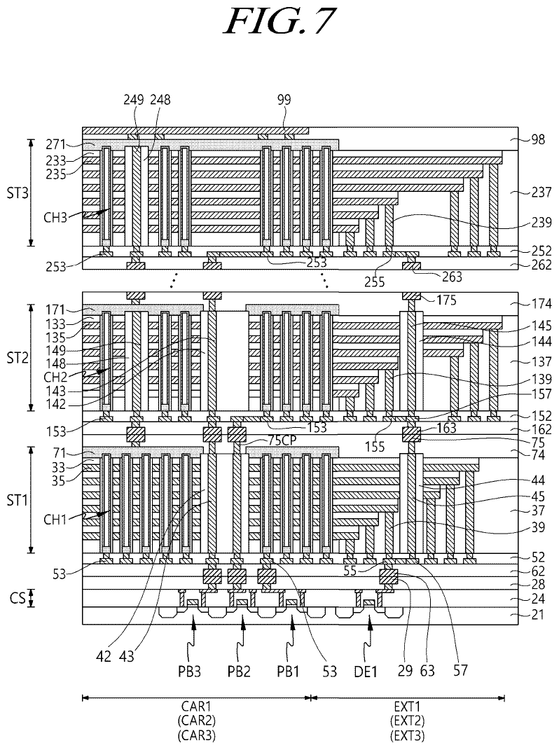

Referring to FIG. 7, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a plurality of first bit through electrodes 43, a first slim insulating block 44, a first slim through electrode 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a plurality of bit contact plugs 75CP, a second stack structure ST2, a plurality of second channel structures CH2, an upper insulating layer 98, a source interconnection 99, a second buried insulating layer 137, a plurality of second contact plugs 139, a second bit insulating block 142, a second bit through electrode 143, a second slim insulating block 144, a second slim through electrode 145, a first source insulating block 148, a first source through electrode 149, a second interlayer insulating layer 152, a plurality of second interconnections 153, 155 and 157, a fourth insulating bonding layer 162, a plurality of fourth bonding pads 163, a second source line 171, a fifth insulating bonding layer 174, a plurality of fifth bonding pads 175, a third stack structure ST3, a third buried insulating layer 237, a plurality of third contact plugs 239, a plurality of third channel structures CH3, a second source insulating block 248, a second source through electrode 249, a third interlayer insulating layer 252, a plurality of third interconnections 253 and 255, a sixth insulating bonding layer 262, a plurality of sixth bonding pads 263, and a third source line 271.

The circuit structure CS may include a first page buffer PB1, a second page buffer PB2, a third page buffer PB3, a first decoder DE1 and a circuit insulating layer 24. Each of the plurality of first bonding pads 29 may be connected to a corresponding one among the first page buffer PB1, the second page buffer PB2, the third page buffer PB3 and the first decoder DE1. The plurality of second interconnections 153, 155 and 157 may include a plurality of second bit lines 153, a plurality of third word interconnections 155 and a fourth word interconnection 157.

In an embodiment, one selected among the plurality of first channel structures CH1 may be connected to the first page buffer PB1, one selected among the plurality of second channel structures CH2 may be connected to the second page buffer PB2, and one selected among the plurality of third channel structures CH3 may be connected to the third page buffer PB3. For example, one selected among the plurality of first channel structures CH1 may be connected to the first page buffer PB1 through a corresponding one among the plurality of first bit lines 53, a corresponding one among the plurality of second bonding pads 63 and a corresponding one among the plurality of first bonding pads 29. One selected among the plurality of second channel structures CH2 may be connected to the second page buffer PB2 through a corresponding one among the plurality of second bit lines 153, a corresponding one among the plurality of fourth bonding pads 163, a corresponding one among the plurality of third bonding pads 75, a corresponding one among the plurality of bit contact plugs 75CP, a corresponding one among the plurality of first bit through electrodes 43, a corresponding one among the plurality of second bonding pads 63 and a corresponding one among the plurality of first bonding pads 29.

One selected among the plurality of third channel structures CH3 may be connected to the third page buffer PB3 through a corresponding one among the plurality of third bit lines 253, a corresponding one among the plurality of sixth bonding pads 263, a corresponding one among the plurality of fifth bonding pads 175, the second bit through electrode 143, a corresponding one among the plurality of fourth bonding pads 163, a corresponding one among the plurality of third bonding pads 75, a corresponding one among the plurality of bit contact plugs 75CP, a corresponding one among the plurality of first bit through electrodes 43, a corresponding one among the plurality of second bonding pads 63 and a corresponding one among the plurality of first bonding pads 29.

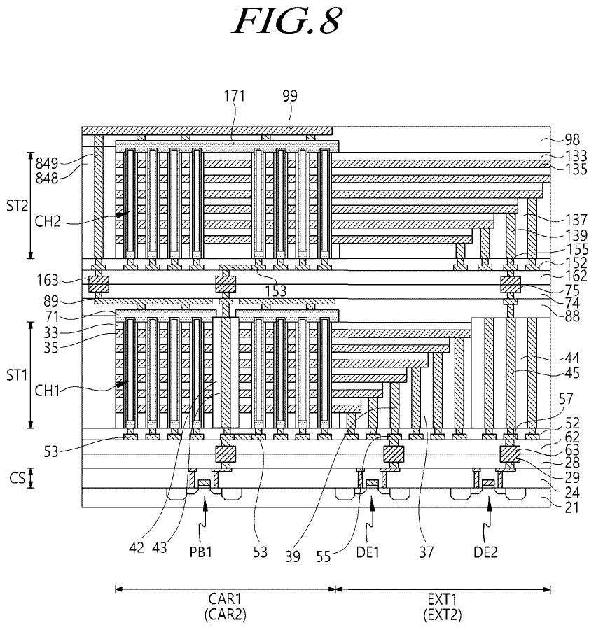

Referring to FIG. 8, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a plurality of first slim through electrodes 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a second stack structure ST2, a plurality of second channel structures CH2, a fourth interlayer insulating layer 88, an intermediate interconnection 89, an upper insulating layer 98, a source interconnection 99, a second buried insulating layer 137, a plurality of second contact plugs 139, a second interlayer insulating layer 152, a plurality of second interconnections 153 and 155, a fourth insulating bonding layer 162, a plurality of fourth bonding pads 163, a second source line 171, an external source insulating block 848, and an external source through electrode 849.

The fourth interlayer insulating layer 88 may be disposed on the first source line 71 and the first stack structure ST1. The intermediate interconnection 89 may be disposed in the fourth interlayer insulating layer 88. The intermediate interconnection 89 may be connected to the first source line 71. In an embodiment, the intermediate interconnection 89 may serve to reduce the interconnection resistance of the first source line 71.

The third insulating bonding layer 74 may be disposed on the fourth interlayer insulating layer 88 and the intermediate interconnection 89. The plurality of third bonding pads 75 may be disposed in the third insulating bonding layer 74. One selected among the plurality of third bonding pads 75 may be connected to the intermediate interconnection 89. Another one selected among the plurality of third bonding pads 75 may be connected to the first bit through electrode 43. Still another one selected among the plurality of third bonding pads 75 may be connected to the first slim through electrode 45.

The external source through electrode 849 may be disposed in the external source insulating block 848. The external source insulating block 848 and the external source through electrode 849 may be disposed outside a second cell area CAR2. The second interlayer insulating layer 152 may be disposed on one surfaces (e.g., lower surfaces) of the second stack structure ST2, the plurality of second channel structures CH2, the second buried insulating layer 137, the plurality of second contact plugs 139, the external source insulating block 848 and the external source through electrode 849. The fourth insulating bonding layer 162 may be disposed on the second interlayer insulating layer 152 and the plurality of second interconnections 153 and 155. One selected among the plurality of fourth bonding pads 163 may be connected to the external source through electrode 849.

The upper insulating layer 98 may be disposed on the second source line 171, the second stack structure ST2, the external source insulating block 848 and the external source through electrode 849. The source interconnection 99 may be disposed in the upper insulating layer 98. The source interconnection 99 may be connected to the second source line 171 and the external source through electrode 849.

In an embodiment, the second source line 171 may be connected to the first source line 71 through the source interconnection 99, the external source through electrode 849, a corresponding one among the plurality of fourth bonding pads 163, a corresponding one among the plurality of third bonding pads 75 and the intermediate interconnection 89. The first source line 71 and the second source line 171 may be controlled to an on or off state at the same time or at least partially overlapping intervals of time.

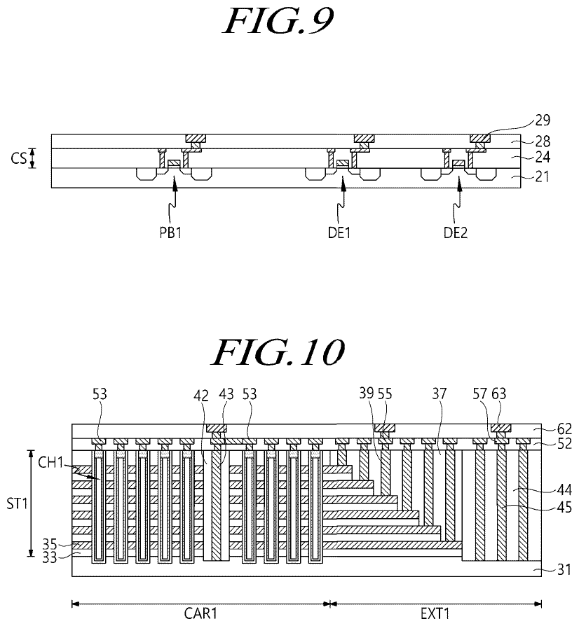

FIGS. 9 to 16 are cross-sectional views for explaining a method of forming a semiconductor device based on an embodiment of the disclosed technology.

Referring to FIG. 9, a circuit structure CS may be formed on a first substrate 21. A first insulating bonding layer 28 and a plurality of first bonding pads 29 may be formed on the circuit structure CS.

The first substrate 21 may include a semiconductor substrate such as a silicon wafer or an SOI (silicon on insulator) wafer. The first substrate 21 may include a III-V group semiconductor substrate, for example, a compound semiconductor substrate such as GaAs. The first substrate 21 may include monocrystalline silicon, polysilicon, amorphous silicon, monocrystalline silicon germanium, polycrystalline silicon germanium, carbon-doped silicon, or a combination thereof. The circuit structure CS may be formed in and/or on the first substrate 21.

The circuit structure CS may include various types of active/passive elements such as transistors. The transistor may include a planar transistor, a recess channel transistor, a vertical transistor, a fin field effect transistor (finFET), a gate all around (GAA) transistor, a multi-bridge channel transistor, or a combination thereof. In an embodiment, the circuit structure CS may include a first page buffer PB1, a first decoder DE1, a second decoder DE2 and a circuit insulating layer 24.

In an embodiment, each of the first page buffer PB1, the first decoder DE1 and the second decoder DE2 may include a logic circuit which has one or a plurality of transistors. The transistor included in each of the first page buffer PB1, the first decoder DE1 and the second decoder DE2 may include a plurality of components such as a gate, a source and a drain. The components of the transistor may be formed in and/or on the substrate 21. For example, the components of the transistor such as the source and the drain may be formed in the substrate 21 using an ion implantation process.

The circuit insulating layer 24 may be formed on the first substrate 21 to cover the first page buffer PB1, the first decoder DE1 and the second decoder DE2. The first insulating bonding layer 28 may cover the circuit structure CS. The plurality of first bonding pads 29 may be formed in the first insulating bonding layer 28. The upper surfaces of the first insulating bonding layer 28 and the plurality of first bonding pads 29 may form substantially the same plane. Each of the plurality of first bonding pads 29 may be electrically connected to corresponding at least one among the first page buffer PB1, the first decoder DE1 and the second decoder DE2. In an embodiment, each of the plurality of first bonding pads 29 may be connected to the source/drain of a transistor included in a corresponding one among the first page buffer PB1, the first decoder DE1 and the second decoder DE2.

Each of the circuit insulating layer 24 and the first insulating bonding layer 28 may include a single layer or a multilayer. Each of the circuit insulating layer 24 and the first insulating bonding layer 28 may include at least two selected from the group consisting of Si, O, N, C and B. Each of the circuit insulating layer 24 and the first insulating bonding layer 28 may include silicon oxide, silicon nitride, silicon oxynitride, silicon carbonitride (SiCN), silicon oxycarbonitride (SiOCN), low-k dielectric, high-k dielectric, or a combination thereof. In an embodiment, the first insulating bonding layer 28 may include silicon carbonitride (SiCN).

The plurality of first bonding pads 29 may include may include a single layer or a multilayer. The plurality of first bonding pads 29 may include metal, metal nitride, metal oxide, metal silicide, polysilicon, conductive carbon, or a combination thereof. The plurality of first bonding pads 29 may include Cu, Al, Ni, Co, Ru, W, WN, Ti, TiN, Ta, TaN, Sn, Pt, Au, Ag, or a combination thereof. In an embodiment, the plurality of first bonding pads 29 may include a Cu layer which is formed using an electroplating method.

Referring to FIG. 10, a first stack structure ST1 may be formed on a second substrate 31. The first stack structure ST1 may include a plurality of first insulating layers 33 and a plurality of first horizontal electrodes 35 which are alternately stacked. The first stack structure ST1 may include a first cell area CAR1 and a first connection area EXT1. The first connection area EXT1 may be continuous to the side surface of the first cell area CAR1. The first connection area EXT1 may be referred to as a slim or a slim area. In the first connection area EXT1, the plurality of first insulating layers 33 and the plurality of first horizontal electrodes 35 may have step-shaped structures. A first buried insulating layer 37 may be formed on the plurality of first insulating layers 33 and the plurality of first horizontal electrodes 35 in the first connection area EXT1.

A plurality of first channel structures CH1 which extend into the second substrate 31 by passing through the first stack structure ST1 may be formed. The plurality of first channel structures CH1 may be formed in the first cell area CAR1. As illustrated in FIG. 2, each of the plurality of first channel structures CH1 may include a core layer CO, a channel pattern CP, an information storage pattern DSL and a drain pad DP. The information storage pattern DSL may include a tunnel layer TL, a charge trap layer CTL and a blocking layer BL.

In an embodiment, the core layer CO may include silicon oxide, silicon nitride, silicon oxynitride, polysilicon, or a combination thereof. The channel pattern CP may include a semiconductor material such as polysilicon. The drain pad DP may include a semiconductor material such as polysilicon. The tunnel layer TL may include silicon oxide, the charge trap layer CTL may include silicon nitride, and the blocking layer BL may include silicon oxide.

A plurality of first contact plugs 39 which are connected to the plurality of first horizontal electrodes 35 by passing through the first buried insulating layer 37 may be formed in the first connection area EXT1. A first bit insulating block 42 which extends into the second substrate 31 by passing through the first stack structure ST1 may be formed in the first cell area CAR1. A first bit through electrode 43 may be formed in the first bit insulating block 42. The first bit through electrode 43 may extend into the second substrate 31 by passing through the first stack structure ST1. The first bit through electrode 43 may be insulated from the plurality of first horizontal electrodes 35 by the first bit insulating block 42.

A first slim insulating block 44 which extends into the second substrate 31 by passing through the first buried insulating layer 37, the plurality of first horizontal electrodes 35 and the plurality of first insulating layers 33 may be formed in the first connection area EXT1. A plurality of first slim through electrodes 45 may be formed in the first slim insulating block 44. The plurality of first slim through electrodes 45 may extend into the second substrate 31 by passing through the first buried insulating layer 37, the plurality of first horizontal electrodes 35 and the plurality of first insulating layers 33. The plurality of first slim through electrodes 45 may be insulated from the plurality of first horizontal electrodes 35 by the first slim insulating block 44.

A first interlayer insulating layer 52 may be formed on the first stack structure ST1, the plurality of first channel structures CH1, the plurality of first contact plugs 39, the first bit insulating block 42, the first bit through electrode 43, the first slim insulating block 44 and the plurality of first slim through electrodes 45. A plurality of first interconnections 53, 55 and 57 may be formed in the first interlayer insulating layer 52.

The plurality of first interconnections 53, 55 and 57 may include a plurality of first bit lines 53, a plurality of first word interconnections 55 and a plurality of second word interconnections 57. Each of the plurality of first bit lines 53 may be electrically connected to corresponding at least one among the plurality of first channel structures CH1. Each of the plurality of first word interconnections 55 may be electrically connected to corresponding at least one among the plurality of first contact plugs 39. Each of the plurality of second word interconnections 57 may be electrically connected to corresponding at least one among the plurality of first slim through electrodes 45. For the sake of convenience in explanation, the plurality of first interconnections 53, 55 and 57 are illustrated as being formed on the same layer, but may be formed on different layers.

A second insulating bonding layer 62 may be formed on the first interlayer insulating layer 52. A plurality of second bonding pads 63 may be formed in the second insulating bonding layer 62. The upper surfaces of the second insulating bonding layer 62 and the plurality of second bonding pads 63 may form substantially the same plane. Each of the plurality of second bonding pads 63 may be electrically connected to a corresponding one among the plurality of first interconnections 53, 55 and 57 and the first bit through electrode 43. In an embodiment, one selected among the plurality of second bonding pads 63 may be connected to one selected among the plurality of first bit lines 53 and the first bit through electrode 43.

The second substrate 31 may include a material similar to the first substrate 21. Each of the plurality of first insulating layers 33, the first buried insulating layer 37, the first bit insulating block 42, the first slim insulating block 44, the first interlayer insulating layer 52 and the second insulating bonding layer 62 may include a single layer or a multilayer. Each of the plurality of first insulating layers 33, the first buried insulating layer 37, the first bit insulating block 42, the first slim insulating block 44, the first interlayer insulating layer 52 and the second insulating bonding layer 62 may include at least two selected from the group consisting of Si, O, N, C and B. Each of the plurality of first insulating layers 33, the first buried insulating layer 37, the first bit insulating block 42, the first slim insulating block 44, the first interlayer insulating layer 52 and the second insulating bonding layer 62 may include silicon oxide, silicon nitride, silicon oxynitride, silicon carbonitride (SiCN), silicon oxycarbonitride (SiOCN), low-k dielectric, high-k dielectric, or a combination thereof. The second insulating bonding layer 62 may include a material similar to the first insulating bonding layer 28. In an embodiment, the second insulating bonding layer 62 may include silicon carbonitride (SiCN). In an embodiment, the plurality of first insulating layers 33 and the plurality of first horizontal electrodes 35 may be alternately stacked. The plurality of first horizontal electrodes 35 may be disposed between the plurality of first insulating layers 33. The plurality of first insulating layers 33 may serve to provide cavities for forming the plurality of first horizontal electrodes 35. The plurality of first insulating layers 33 may serve to provide electrical insulation between the plurality of first horizontal electrodes 35.

Each of the plurality of first horizontal electrodes 35, the plurality of first contact plugs 39, the first bit through electrode 43, the plurality of first slim through electrodes 45, the plurality of first interconnections 53, 55 and 57 and the plurality of second bonding pads 63 may include a single layer or a multilayer. Each of the plurality of first horizontal electrodes 35, the plurality of first contact plugs 39, the first bit through electrode 43, the plurality of first slim through electrodes 45, the plurality of first interconnections 53, 55 and 57 and the plurality of second bonding pads 63 may include metal, metal nitride, metal oxide, metal silicide, polysilicon, conductive carbon, or a combination thereof. Each of the plurality of first horizontal electrodes 35, the plurality of first contact plugs 39, the first bit through electrode 43, the plurality of first slim through electrodes 45, the plurality of first interconnections 53, 55 and 57 and the plurality of second bonding pads 63 may include Cu, Al, Ni, Co, Ru, W, WN, Ti, TiN, Ta, TaN, Sn, Pt, Au, Ag, or a combination thereof. The plurality of second bonding pads 63 may include a material similar to the plurality of first bonding pads 29. In an embodiment, the plurality of second bonding pads 63 may include a Cu layer which is formed using an electroplating method.

Referring to FIG. 11, the second substrate 31 which includes the first stack structure ST1 may be bonded onto the first substrate 21 which includes the circuit structure CS. The first insulating bonding layer 28 and the second insulating bonding layer 62 may be bonded to face each other, and the plurality of first bonding pads 29 and the plurality of second bonding pads 63 may be bonded to face each other.

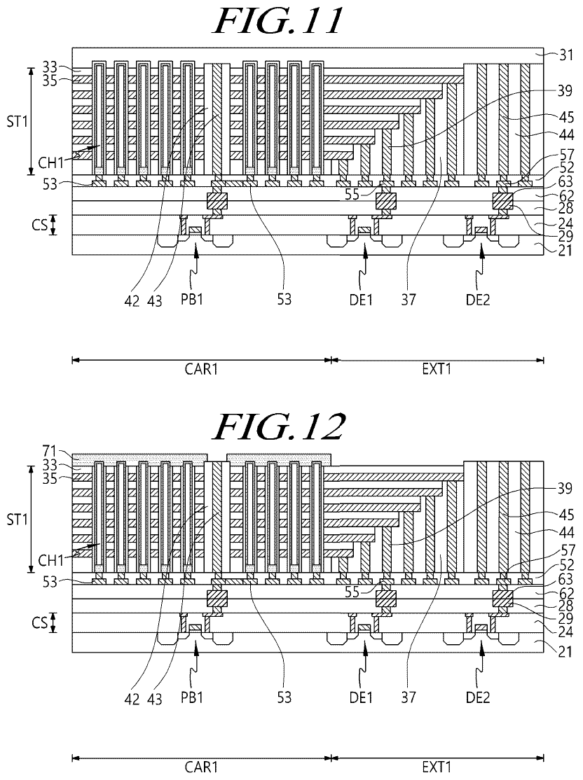

Referring to FIG. 12, by removing the second substrate 31, one ends of the first stack structure ST1, the plurality of first channel structures CH1, the first bit insulating block 42, the first bit through electrode 43, the first slim insulating block 44 and the plurality of first slim through electrodes 45 may be exposed. By partially removing the information storage pattern DSL, the channel pattern CP which is included in each of the plurality of first channel structures CH1 may be partially exposed.

A first source line 71 which covers the plurality of first channel structures CH1 may be formed on the first stack structure ST1. The channel pattern CP may extend into the first source line 71. The channel pattern CP may directly contact the first source line 71. The first source line 71 may include a semiconductor material such as polysilicon.

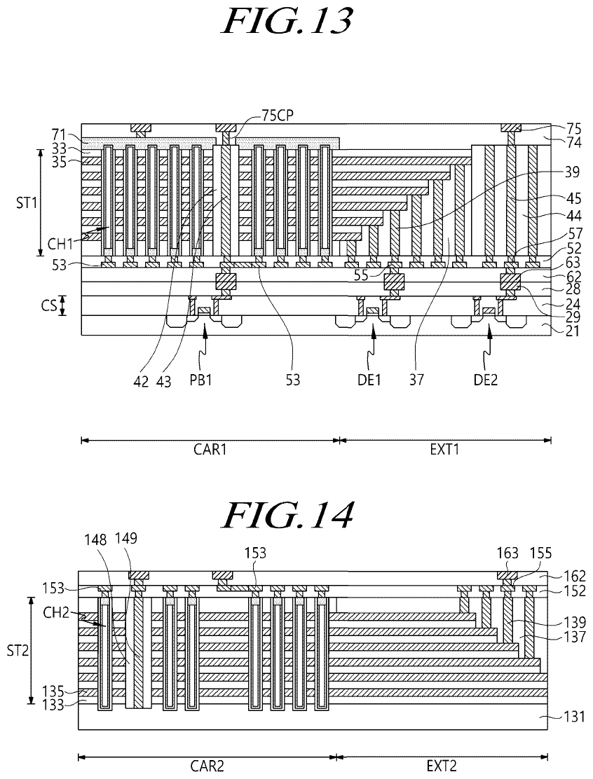

Referring to FIG. 13, a third insulating bonding layer 74 may be formed on the first stack structure ST1, the first source line 71, the first bit insulating block 42, the first bit through electrode 43, the first slim insulating block 44 and the plurality of first slim through electrodes 45. A plurality of third bonding pads 75 may be formed in the third insulating bonding layer 74. The upper surfaces of the third insulating bonding layer 74 and the plurality of third bonding pads 75 may form substantially the same plane. Each of the plurality of third bonding pads 75 may be electrically connected to a corresponding one among the first source line 71, the first bit through electrode 43 and the plurality of first slim through electrodes 45.

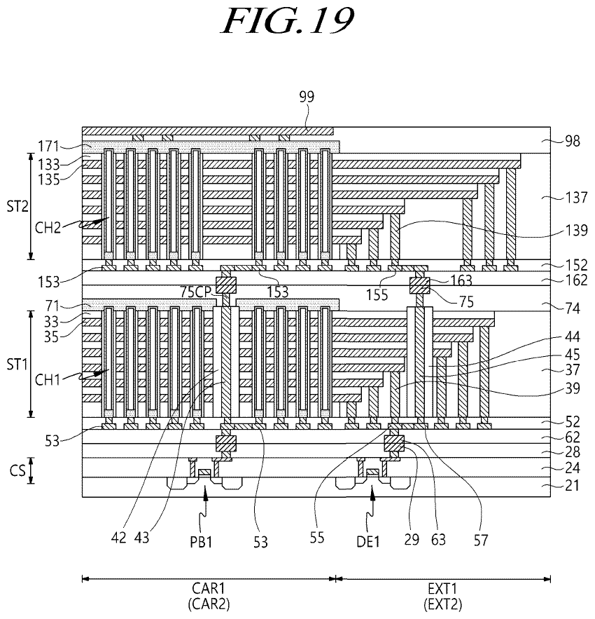

In an embodiment, a bit contact plug 75CP may be formed between the plurality of third bonding pads 75 and the first bit through electrode 43. The third insulating bonding layer 74 may contact the first bit insulating block 42 by passing through the first source line 71. The bit contact plug 75CP may pass through the third insulating bonding layer 74 and the first source line 71, and may contact one selected among the plurality of third bonding pads 75 and the first bit through electrode 43. In an embodiment, an interface between the bit contact plug 75CP and the first bit through electrode 43 is disposed between an upper surface and a lower surface of the first source line 71 as shown in FIG. 19.

The third insulating bonding layer 74 may include a material similar to the second insulating bonding layer 62 and/or the first insulating bonding layer 28. In an embodiment, the third insulating bonding layer 74 may include silicon carbonitride (SiCN).

The plurality of third bonding pads 75 and the bit contact plug 75CP may include a material similar to the plurality of second bonding pads 63 and/or the plurality of first bonding pads 29. In an embodiment, the plurality of third bonding pads 75 may include a Cu layer which is formed using an electroplating method.

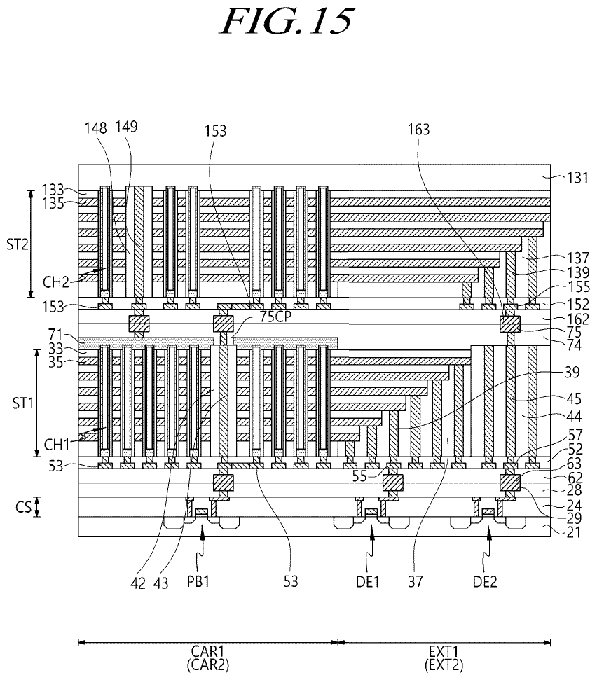

Referring to FIG. 14, a second stack structure ST2 may be formed on a third substrate 131. The second stack structure ST2 may include a plurality of second insulating layers 133 and a plurality of second horizontal electrodes 135 which are alternately stacked. The second stack structure ST2 may include a second cell area CAR2 and a second connection area EXT2. The second connection area EXT2 may be continuous to the side surface of the second cell area CAR2. The second connection area EXT2 may be referred to as a slim or a slim area. In the second connection area EXT2, the plurality of second insulating layers 133 and the plurality of second horizontal electrodes 135 may have step-shaped structures. A second buried insulating layer 137 may be formed on the plurality of second insulating layers 133 and the plurality of second horizontal electrodes 135 in the second connection area EXT2.

A plurality of second channel structures CH2 which extend into the third substrate 131 by passing through the second stack structure ST2 may be formed. The plurality of second channel structures CH2 may be formed in the second cell area CAR2. As illustrated in FIG. 2, each of the plurality of second channel structures CH2 may include a core layer CO, a channel pattern CP, an information storage pattern DSL and a drain pad DP.

A plurality of second contact plugs 139 which are connected to the plurality of second horizontal electrodes 135 by passing through the second buried insulating layer 137 may be formed in the second connection area EXT2. A first source insulating block 148 which extends into the third substrate 131 by passing through the second stack structure ST2 may be formed in the second cell area CAR2. A first source through electrode 149 may be formed in the first source insulating block 148. The first source through electrode 149 may extend into the third substrate 131 by passing through the second stack structure ST2. The first source through electrode 149 may be insulated from the plurality of second horizontal electrodes 135 by the first source insulating block 148.

A second interlayer insulating layer 152 may be formed on the second stack structure ST2, the plurality of second channel structures CH2, the plurality of second contact plugs 139, the first source insulating block 148 and the first source through electrode 149. A plurality of second interconnections 153 and 155 may be formed in the second interlayer insulating layer 152.

The plurality of second interconnections 153 and 155 may include a plurality of second bit lines 153 and a plurality of third word interconnections 155. Each of the plurality of second bit lines 153 may be electrically connected to corresponding at least one among the plurality of second channel structures CH2. Each of the plurality of third word interconnections 155 may be electrically connected to corresponding at least one among the plurality of second contact plugs 139. For the sake of convenience in explanation, the plurality of second interconnections 153 and 155 are illustrated as being formed on the same layer, but may be formed on different layers.

A fourth insulating bonding layer 162 may be formed on the second interlayer insulating layer 152. A plurality of fourth bonding pads 163 may be formed in the fourth insulating bonding layer 162. The upper surfaces of the fourth insulating bonding layer 162 and the plurality of fourth bonding pads 163 may form substantially the same plane. Each of the plurality of fourth bonding pads 163 may be electrically connected to a corresponding one among the plurality of second interconnections 153 and 155 and the first source through electrode 149.

The third substrate 131 may include a material similar to the second substrate 31 and the first substrate 21. Each of the plurality of second insulating layers 133, the second buried insulating layer 137, the first source insulating block 148, the second interlayer insulating layer 152 and the fourth insulating bonding layer 162 may include a single layer or a multilayer. Each of the plurality of second insulating layers 133, the second buried insulating layer 137, the first source insulating block 148, the second interlayer insulating layer 152 and the fourth insulating bonding layer 162 may include at least two selected from the group consisting of Si, O, N, C and B. Each of the plurality of second insulating layers 133, the second buried insulating layer 137, the first source insulating block 148, the second interlayer insulating layer 152 and the fourth insulating bonding layer 162 may include silicon oxide, silicon nitride, silicon oxynitride, silicon carbonitride (SiCN), silicon oxycarbonitride (SiOCN), low-k dielectric, high-k dielectric, or a combination thereof.

The plurality of second insulating layers 133 may include a material similar to the plurality of first insulating layers 33. The second buried insulating layer 137 may include a material similar to the first buried insulating layer 37. The fourth insulating bonding layer 162 may include a material similar to the third insulating bonding layer 74, the second insulating bonding layer 62 and/or the first insulating bonding layer 28. In an embodiment, the fourth insulating bonding layer 162 may include silicon carbonitride (SiCN).

Each of the plurality of second horizontal electrodes 135, the plurality of second contact plugs 139, the first source through electrode 149, the plurality of second interconnections 153 and 155 and the plurality of fourth bonding pads 163 may include a single layer or a multilayer. Each of the plurality of second horizontal electrodes 135, the plurality of second contact plugs 139, the first source through electrode 149, the plurality of second interconnections 153 and 155 and the plurality of fourth bonding pads 163 may include metal, metal nitride, metal oxide, metal silicide, polysilicon, conductive carbon, or a combination thereof. Each of the plurality of second horizontal electrodes 135, the plurality of second contact plugs 139, the first source through electrode 149, the plurality of second interconnections 153 and 155 and the plurality of fourth bonding pads 163 may include Cu, Al, Ni, Co, Ru, W, WN, Ti, TiN, Ta, TaN, Sn, Pt, Au, Ag, or a combination thereof. The plurality of fourth bonding pads 163 may include a material similar to the plurality of third bonding pads 75, the plurality of second bonding pads 63 and/or the plurality of first bonding pads 29. In an embodiment, the plurality of fourth bonding pads 163 may include a Cu layer which is formed using an electroplating method.

Referring to FIG. 15, the third substrate 131 which includes the second stack structure ST2 may be bonded onto the first stack structure ST1 and the first source line 71. The third insulating bonding layer 74 and the fourth insulating bonding layer 162 may be bonded to face each other, and the plurality of third bonding pads 75 and the plurality of fourth bonding pads 163 may be bonded to face each other.

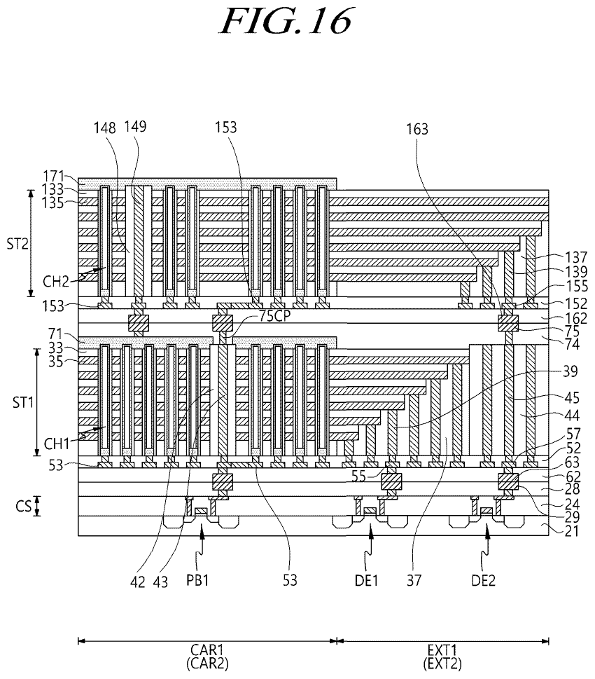

Referring to FIG. 16, by removing the third substrate 131, one ends of the second stack structure ST2, the plurality of second channel structures CH2, the first source insulating block 148 and the first source through electrode 149 may be exposed. By partially removing the information storage pattern DSL, the channel pattern CP which is included in each of the plurality of second channel structures CH2 may be partially exposed.

A second source line 171 which covers the plurality of second channel structures CH2 and the first source through electrode 149 may be formed on the second stack structure ST2. The channel pattern CP which is included in each of the plurality of second channel structures CH2 may extend into the second source line 171. The channel pattern CP may directly contact the second source line 171. The first source through electrode 149 may extend into the second source line 171. The first source through electrode 149 may directly contact the second source line 171. In an embodiment, an uppermost end of the first source through electrode 149 is disposed at a level higher than a lowermost end of the second source line 171 as shown in FIG. 4. The second source line 171 may include a material similar to the first source line 71. The second source line 171 may include a semiconductor material such as polysilicon.

Referring to FIG. 3 again, an upper insulating layer 98 may be formed on the second stack structure ST2 and the second source line 171. A source interconnection 99 may be formed in the upper insulating layer 98. The source interconnection 99 may be connected to the second source line 171.

The upper insulating layer 98 may include a single layer or a multilayer. The upper insulating layer 98 may include at least two selected from the group consisting of Si, O, N, C and B. The upper insulating layer 98 may include silicon oxide, silicon nitride, silicon oxynitride, silicon carbonitride (SiCN), silicon oxycarbonitride (SiOCN), low-k dielectric, high-k dielectric, or a combination thereof.

The source interconnection 99 may include a single layer or a multilayer. The source interconnection 99 may include metal, metal nitride, metal oxide, metal silicide, polysilicon, conductive carbon, or a combination thereof. The source interconnection 99 may include Cu, Al, Ni, Co, Ru, W, WN, Ti, TiN, Ta, TaN, Sn, Pt, Au, Ag, or a combination thereof. In an embodiment, the source interconnection 99 may include a material with lower electrical resistance than the second source line 171.

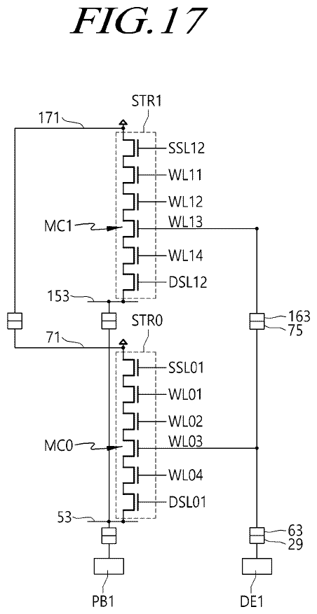

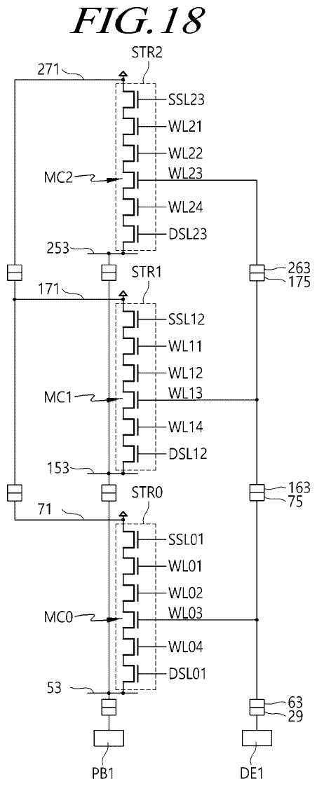

FIGS. 17 and 18 are equivalent circuit diagrams for explaining semiconductor devices based on embodiments of the disclosed technology.

Referring to FIG. 17, a semiconductor device based on an embodiment of the disclosed technology may include a first page buffer PB1, a first decoder DE1, a plurality of first bonding pads 29, a plurality of second bonding pads 63, a first bit line 53, a second bit line 153, a first source line 71, a second source line 171, a plurality of third bonding pads 75, a plurality of fourth bonding pads 163, a first drain select line DSL01, a second drain select line DSL12, a first source select line SSL01, a second source select line SSL12, a first string STR0, a second string STR1, and a plurality of word lines WL01, WL02, WL03, WL04, WL11, WL12, WL13 and WL14.

Referring once again to FIGS. 1, 2 and 17, the first string STR0 may be disposed in the first stack structure ST1. Among the plurality of first horizontal electrodes 35, one adjacent to an uppermost end may correspond to the first source select line SSL01. Among the plurality of first horizontal electrodes 35, one adjacent to a lowermost end may correspond to the first drain select line DSL01. Among the plurality of first horizontal electrodes 35, some disposed between the first source select line SSL01 and the first drain select line DSL01 may correspond to first to fourth word lines WL01, WL02, WL03 and WL04. A plurality of first memory cells MC0 may be provided at intersections of the first channel structure CH1 and the first to fourth word lines WL01, WL02, WL03 and WL04. The first string STR0 may include the plurality of first memory cells MC0. One end (e.g., the upper end) of the first string STR0 may be connected to the first source line 71. The other end (e.g., the lower end) of the first string STR0 may be connected to the first bit line 53.

The second string STR1 may be disposed in the second stack structure ST2. Among the plurality of second horizontal electrodes 135, one adjacent to an uppermost end may correspond to the second source select line SSL12. Among the plurality of second horizontal electrodes 135, one adjacent to a lowermost end may correspond to the second drain select line DSL12. Among the plurality of second horizontal electrodes 135, some disposed between the second source select line SSL12 and the second drain select line DSL12 may correspond to fifth to eighth word lines WL11, WL12, WL13 and WL14. A plurality of second memory cells MC1 may be provided at intersections of the second channel structure CH2 and the fifth to eighth word lines WL11, WL12, WL13 and WL14. The second string STR1 may include the plurality of second memory cells MC1. One end (e.g., the upper end) of the second string STR1 may be connected to the second source line 171. The other end (e.g., the lower end) of the second string STR1 may be connected to the second bit line 153.

In an embodiment, the first source line 71 may be connected to the second source line 171 through the third bonding pad 75, the fourth bonding pad 163 and the first source through electrode 149.

In an embodiment, the first string STR0 and the second string STR1 may be connected to the first page buffer PB1. The first bit line 53 and the second bit line 153 may be connected to the first page buffer PB1 through the second bonding pad 63 and the first bonding pad 29. For example, the second bit line 153 may be connected to the second bonding pad 63 through the fourth bonding pad 163, the third bonding pad 75, the bit contact plug 75CP and the first bit through electrode 43, and the first bit line 53 may be connected to the second bonding pad 63.

In an embodiment, the third word line WL03 and the seventh word line WL13 may be connected to the first decoder DE1 through the second bonding pad 63 and the first bonding pad 29. For example, the seventh word line WL13 may be connected to the second bonding pad 63 through the second contact plug 139, the third word interconnection 155, the fourth bonding pad 163, the third bonding pad 75, the first slim through electrode 45 and the second word interconnection 57, and the third word line WL03 may be connected to the second bonding pad 63 through the first contact plug 39 and the first word interconnection 55.

In an embodiment, the first string STR0 may be selected by the first source select line SSL01 and the first drain select line DSL01. The second string STR1 may be selected by the second source select line SSL12 and the second drain select line DSL12. The plurality of first memory cells MC0 may be selected by the first source select line SSL01 and the first drain select line DSL01. The plurality of second memory cells MC1 may be selected by the second source select line SSL12 and the second drain select line DSL12.

Referring to FIG. 18, a semiconductor device based on an embodiment of the disclosed technology may include a first page buffer PB1, a first decoder DE1, a plurality of first bonding pads 29, a plurality of second bonding pads 63, a plurality of third bonding pads 75, a plurality of fourth bonding pads 163, a plurality of fifth bonding pads 175, a plurality of sixth bonding pads 263, a first bit line 53, a second bit line 153, a third bit line 253, a first source line 71, a second source line 171, a third source line 271, a first drain select line DSL01, a second drain select line DSL12, a third drain select line DSL23, a first source select line SSL01, a second source select line SSL12, a third source select line SSL23, a first string STR0, a second string STR1, a third string STR2, and a plurality of word lines WL01, WL02, WL03, WL04, WL11, WL12, WL13, WL14, WL21, WL22, WL23 and WL24.

Referring once again to FIGS. 5 and 18, the third string STR2 may be disposed in the third stack structure ST3. Among the plurality of third horizontal electrodes 235, one adjacent to an uppermost end may correspond to the third source select line SSL23. Among the plurality of third horizontal electrodes 235, one adjacent to a lowermost end may correspond to the third drain select line DSL23. Among the plurality of third horizontal electrodes 235, some disposed between the third source select line SSL23 and the third drain select line DSL23 may correspond to ninth to twelfth word lines WL21, WL22, WL23 and WL24. A plurality of third memory cells MC2 may be provided at intersections of the third channel structure CH3 and the ninth to twelfth word lines WL21, WL22, WL23 and WL24. The third string STR2 may include the plurality of third memory cells MC2. One end (e.g., the upper end) of the third string STR2 may be connected to the third source line 271. The other end (e.g., the lower end) of the third string STR2 may be connected to the third bit line 253.

In an embodiment, the first source line 71 may be connected to the second source line 171 through the third bonding pad 75, the fourth bonding pad 163 and the first source through electrode 149. The second source line 171 may be connected to the third source line 271 through the fifth bonding pad 175, the sixth bonding pad 263 and the second source through electrode 249. The first source line 71, the second source line 171 and the third source line 271 may be electrically connected to each other.

In an embodiment, the first string STR0, the second string STR1 and the third string STR2 may all be connected to the first page buffer PB1. The first bit line 53, the second bit line 153 and the third bit line 253 may be connected to the first page buffer PB1 through the second bonding pad 63 and the first bonding pad 29. For example, the third bit line 253 may be connected to the second bonding pad 63 through the sixth bonding pad 263, the fifth bonding pad 175, the second bit through electrode 143, the fourth bonding pad 163, the third bonding pad 75, the bit contact plug 75CP and the first bit through electrode 43, the second bit line 153 may be connected to the second bonding pad 63 through the fourth bonding pad 163, the third bonding pad 75, the bit contact plug 75CP and the first bit through electrode 43, and the first bit line 53 may be connected to the second bonding pad 63.

In an embodiment, the third word line WL03, the seventh word line WL13 and the eleventh word line WL23 may all be connected to the first decoder DE1 through the second bonding pad 63 and the first bonding pad 29. For example, the eleventh word line WL23 may be connected to the second bonding pad 63 through the third contact plug 239, the fifth word interconnection 255, the sixth bonding pad 263, the fifth bonding pad 175, the second slim through electrode 145, the fourth word interconnection 157, the fourth bonding pad 163, the third bonding pad 75, the first slim through electrode 45 and the second word interconnection 57, the seventh word line WL13 may be connected to the second bonding pad 63 through the second contact plug 139, the third word interconnection 155, the fourth bonding pad 163, the third bonding pad 75, the first slim through electrode 45 and the second word interconnection 57, and the third word line WL03 may be connected to the second bonding pad 63 through the first contact plug 39 and the first word interconnection 55.

In an embodiment, the first string STR0 may be selected by the first source select line SSL01 and the first drain select line DSL01. The second string STR1 may be selected by the second source select line SSL12 and the second drain select line DSL12. The third string STR2 may be selected by the third source select line SSL23 and the third drain select line DSL23. A plurality of first memory cells MC0 may be selected by the first source select line SSL01 and the first drain select line DSL01. A plurality of second memory cells MC1 may be selected by the second source select line SSL12 and the second drain select line DSL12. A plurality of third memory cells MC2 may be selected by the third source select line SSL23 and the third drain select line DSL23.

FIG. 19 is a cross-sectional view for explaining a semiconductor device based on an embodiment of the disclosed technology.

Referring to FIG. 19, the semiconductor device based on the embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a first slim through electrode 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a bit contact plug 75CP, a second stack structure ST2, a plurality of second channel structures CH2, an upper insulating layer 98, a source interconnection 99, a second buried insulating layer 137, a plurality of second contact plugs 139, a second interlayer insulating layer 152, a plurality of second interconnections 153 and 155, a fourth insulating bonding layer 162, a plurality of fourth bonding pads 163, and a second source line 171.

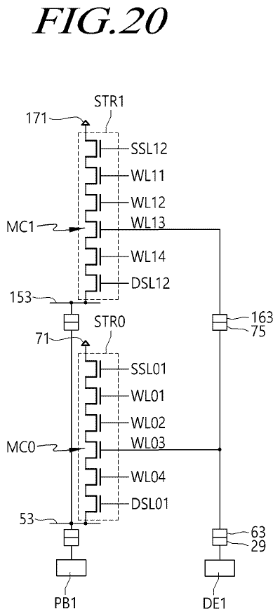

FIG. 20 is an equivalent circuit diagram for explaining a semiconductor device based on an embodiment of the disclosed technology.

Referring to FIG. 20, the semiconductor device based on the embodiment of the disclosed technology may include a first page buffer PB1, a first decoder DE1, a plurality of first bonding pads 29, a plurality of second bonding pads 63, a first bit line 53, a second bit line 153, a first source line 71, a second source line 171, a plurality of third bonding pads 75, a plurality of fourth bonding pads 163, a first drain select line DSL01, a second drain select line DSL12, a first source select line SSL01, a second source select line SSL12, a first string STR0, a second string STR1, and a plurality of word lines WL01, WL02, WL03, WL04, WL11, WL12, WL13 and WL14.

Referring once again to FIGS. 19 and 20, one end (e.g., the upper end) of the first string STR0 may be connected to the first source line 71. The other end (e.g., the lower end) of the first string STR0 may be connected to the first bit line 53. One end (e.g., the upper end) of the second string STR1 may be connected to the second source line 171. The other end (e.g., the lower end) of the second string STR1 may be connected to the second bit line 153.

In an embodiment, the first source line 71 and the second source line 171 may be disconnected from each other. The second source line 171 may be controlled independently from the first source line 71. A bias may be applied to the second source line 171 at a different time point from the first source line 71.

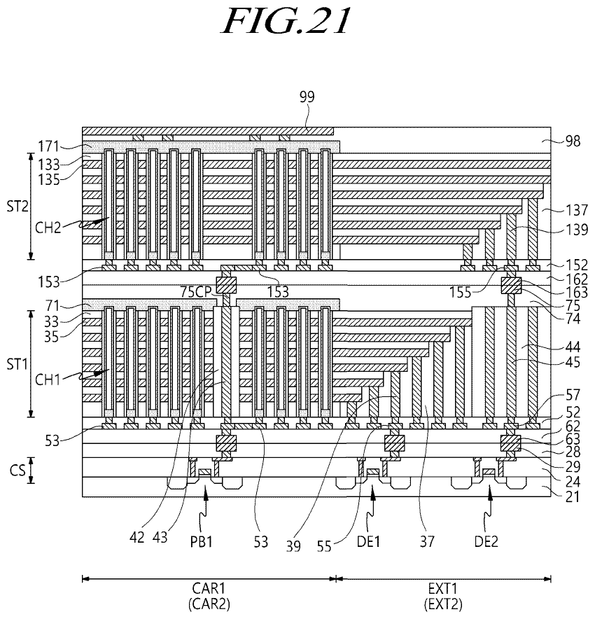

FIGS. 21 to 23 are cross-sectional views for explaining semiconductor devices based on embodiments of the disclosed technology.

Referring to FIG. 21, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a plurality of first slim through electrodes 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a bit contact plug 75CP, a second stack structure ST2, a plurality of second channel structures CH2, an upper insulating layer 98, a source interconnection 99, a second buried insulating layer 137, a plurality of second contact plugs 139, a second interlayer insulating layer 152, a plurality of second interconnections 153 and 155, a fourth insulating bonding layer 162, a plurality of fourth bonding pads 163, and a second source line 171.

The circuit structure CS may include a first page buffer PB1, a first decoder DE1, a second decoder DE2 and a circuit insulating layer 24. Each of the plurality of first bonding pads 29 may be connected to a corresponding one among the first page buffer PB1, the first decoder DE1 and the second decoder DE2.

In an embodiment, the first source line 71 and the second source line 171 may be disconnected from each other. In an embodiment, one selected among the plurality of first channel structures CH1 and one selected among the plurality of second channel structures CH2 may be connected in common to the first page buffer PB1. In an embodiment, one selected among the plurality of first horizontal electrodes 35 may be connected to the first decoder DE1, and one selected among the plurality of second horizontal electrodes 135 may be connected to the second decoder DE2.

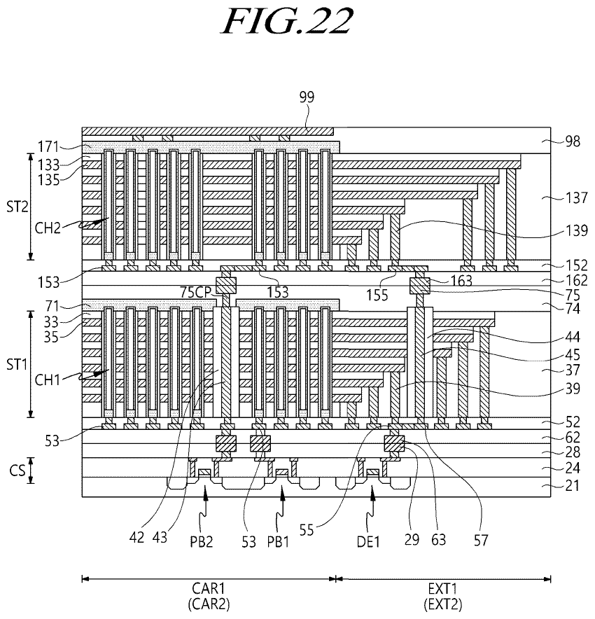

Referring to FIG. 22, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a first slim through electrode 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a bit contact plug 75CP, a second stack structure ST2, a plurality of second channel structures CH2, an upper insulating layer 98, a source interconnection 99, a second buried insulating layer 137, a plurality of second contact plugs 139, a second interlayer insulating layer 152, a plurality of second interconnections 153 and 155, a fourth insulating bonding layer 162, a plurality of fourth bonding pads 163, and a second source line 171.

The circuit structure CS may include a first page buffer PB1, a second page buffer PB2, a first decoder DE1 and a circuit insulating layer 24. Each of the plurality of first bonding pads 29 may be connected to a corresponding one among the first page buffer PB1, the second page buffer PB2 and the first decoder DE1.

In an embodiment, the first source line 71 and the second source line 171 may be disconnected from each other. In an embodiment, one selected among the plurality of first channel structures CH1 may be connected to the first page buffer PB1, and one selected among the plurality of second channel structures CH2 may be connected to the second page buffer PB2. In an embodiment, one selected among the plurality of first horizontal electrodes 35 and one selected among the plurality of second horizontal electrodes 135 may be connected in common to the first decoder DE1.

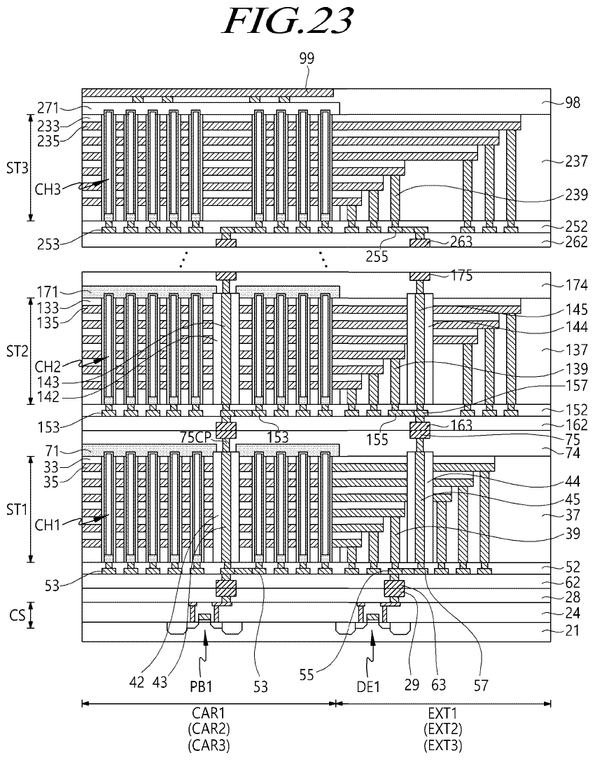

Referring to FIG. 23, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a first slim through electrode 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a bit contact plug 75CP, a second stack structure ST2, a plurality of second channel structures CH2, an upper insulating layer 98, a source interconnection 99, a second buried insulating layer 137, a plurality of second contact plugs 139, a second bit insulating block 142, a second bit through electrode 143, a second slim insulating block 144, a second slim through electrode 145, a second interlayer insulating layer 152, a plurality of second interconnections 153, 155 and 157, a fourth insulating bonding layer 162, a plurality of fourth bonding pads 163, a second source line 171, a fifth insulating bonding layer 174, a plurality of fifth bonding pads 175, a third stack structure ST3, a third buried insulating layer 237, a plurality of third contact plugs 239, a plurality of third channel structures CH3, a third interlayer insulating layer 252, a plurality of third interconnections 253 and 255, a sixth insulating bonding layer 262, a plurality of sixth bonding pads 263, and a third source line 271.

The circuit structure CS may include a first page buffer PB1, a first decoder DE1 and a circuit insulating layer 24. Each of the plurality of first bonding pads 29 may be connected to a corresponding one of the first page buffer PB1 and the first decoder DE1.

In an embodiment, the first source line 71, the second source line 171 and the third source line 271 may be disconnected from each other.

In an embodiment, one selected among the plurality of first channel structures CH1, one selected among the plurality of second channel structures CH2 and one selected among the plurality of third channel structures CH3 may be connected in common to the first page buffer PB1. For example, one selected among the plurality of first channel structures CH1 may be connected to the first page buffer PB1 through a corresponding one among the plurality of first bit lines 53, a corresponding one among the plurality of second bonding pads 63 and a corresponding one among the plurality of first bonding pads 29. One selected among the plurality of second channel structures CH2 may be connected to the first page buffer PB1 through a corresponding one among the plurality of second bit lines 153, a corresponding one among the plurality of fourth bonding pads 163, a corresponding one among the plurality of third bonding pads 75, the bit contact plug 75CP, the first bit through electrode 43, a corresponding one among the plurality of second bonding pads 63 and a corresponding one among the plurality of first bonding pads 29. One selected among the plurality of third channel structures CH3 may be connected to the first page buffer PB1 through a corresponding one among the plurality of third bit lines 253, a corresponding one among the plurality of sixth bonding pads 263, a corresponding one among the plurality of fifth bonding pads 175, the second bit through electrode 143, a corresponding one among the plurality of fourth bonding pads 163, a corresponding one among the plurality of third bonding pads 75, the bit contact plug 75CP, the first bit through electrode 43, a corresponding one among the plurality of second bonding pads 63 and a corresponding one among the plurality of first bonding pads 29.

In an embodiment, one selected among a plurality of first horizontal electrodes 35, one selected among a plurality of second horizontal electrodes 135 and one selected among a plurality of third horizontal electrodes 235 may be connected in common to the first decoder DE1. For example, one selected among the plurality of first horizontal electrodes 35 may be connected to the first decoder DE1 through a corresponding one among the plurality of first contact plugs 39, a corresponding one among the plurality of first word interconnections 55, a corresponding one among the plurality of second bonding pads 63 and a corresponding one among the plurality of first bonding pads 29. One selected among the plurality of second horizontal electrodes 135 may be connected to the first decoder DE1 through a corresponding one among the plurality of second contact plugs 139, a corresponding one among the plurality of third word interconnections 155, the fourth word interconnection 157, a corresponding one among the plurality of fourth bonding pads 163, a corresponding one among the plurality of third bonding pads 75, the first slim through electrode 45, the second word interconnection 57, a corresponding one among the plurality of first word interconnections 55, a corresponding one among the plurality of second bonding pads 63 and a corresponding one among the plurality of first bonding pads 29. One selected among the plurality of third horizontal electrodes 235 may be connected to the first decoder DE1 through a corresponding one among the plurality of third contact plugs 239, a corresponding one among the plurality of fifth word interconnections 255, a corresponding one among the plurality of sixth bonding pads 263, a corresponding one among the plurality of fifth bonding pads 175, the second slim through electrode 145, the fourth word interconnection 157, a corresponding one among the plurality of fourth bonding pads 163, a corresponding one among the plurality of third bonding pads 75, the first slim through electrode 45, the second word interconnection 57, a corresponding one among the plurality of first word interconnections 55, a corresponding one among the plurality of second bonding pads 63 and a corresponding one among the plurality of first bonding pads 29.

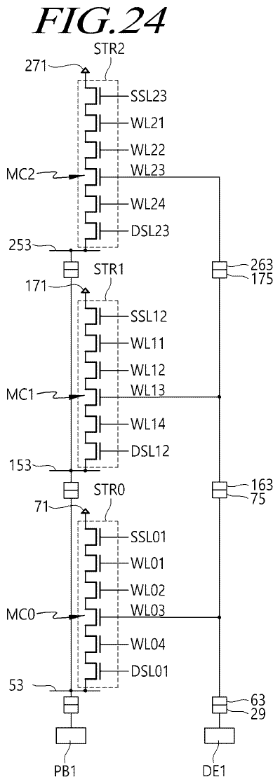

FIG. 24 is an equivalent circuit diagram for explaining a semiconductor device based on an embodiment of the disclosed technology.

Referring to FIG. 24, the semiconductor device based on the embodiment of the disclosed technology may include a first page buffer PB1, a first decoder DE1, a plurality of first bonding pads 29, a plurality of second bonding pads 63, a plurality of third bonding pads 75, a plurality of fourth bonding pads 163, a plurality of fifth bonding pads 175, a plurality of sixth bonding pads 263, a first bit line 53, a second bit line 153, a third bit line 253, a first source line 71, a second source line 171, a third source line 271, a first drain select line DSL01, a second drain select line DSL12, a third drain select line DSL23, a first source select line SSL01, a second source select line SSL12, a third source select line SSL23, a first string STR0, a second string STR1, a third string STR2, and a plurality of word lines WL01, WL02, WL03, WL04, WL11, WL12, WL13, WL14, WL21, WL22, WL23 and WL24.

Referring once again to FIGS. 23 and 24, the first source line 71, the second source line 171 and the third source line 271 may be disconnected from each other. Each of the first source line 71, the second source line 171 and the third source line 271 may be controlled independently. In an embodiment, the first string STR0, the second string STR1 and the third string STR2 may all be connected to the first page buffer PB1. The first bit line 53, the second bit line 153 and the third bit line 253 may be connected to the first page buffer PB1 through the second bonding pad 63 and the first bonding pad 29. In an embodiment, the third word line WL03, the seventh word line WL13 and the eleventh word line WL23 may all be connected to the first decoder DE1 through the second bonding pad 63 and the first bonding pad 29.

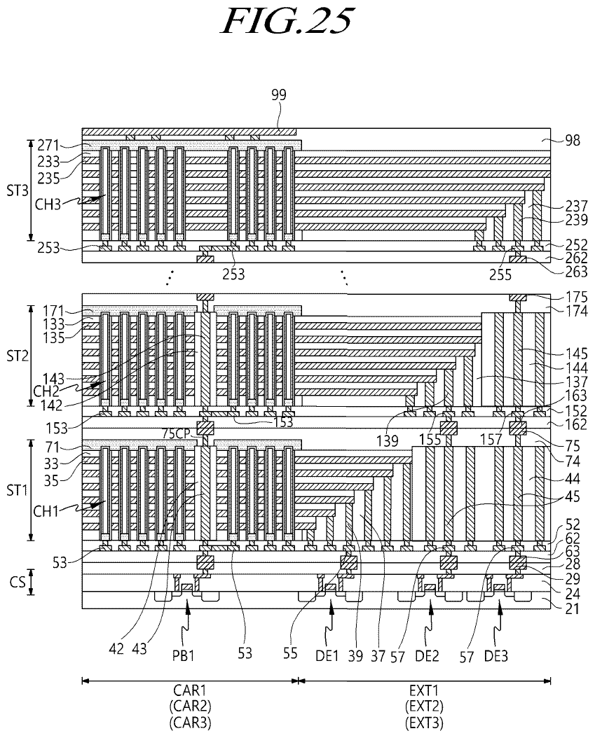

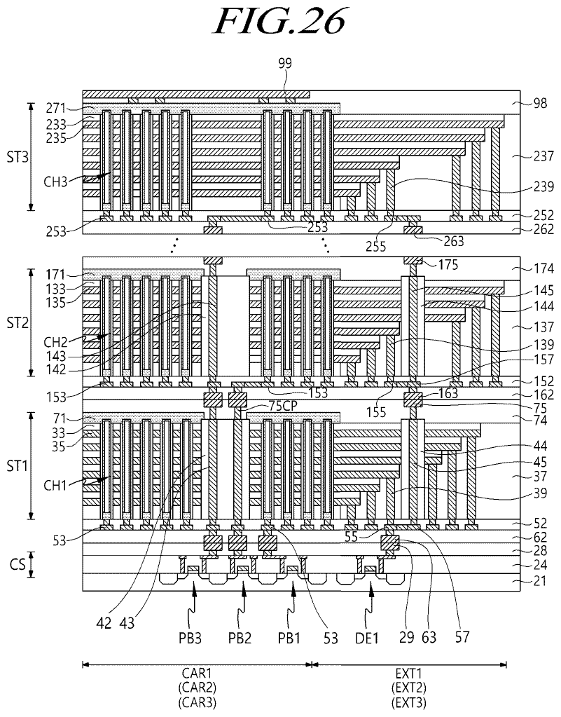

FIGS. 25 and 26 are cross-sectional views for explaining semiconductor devices based on embodiments of the disclosed technology.

Referring to FIG. 25, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a first bit through electrode 43, a first slim insulating block 44, a plurality of first slim through electrodes 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a bit contact plug 75CP, a second stack structure ST2, a plurality of second channel structures CH2, an upper insulating layer 98, a source interconnection 99, a second buried insulating layer 137, a plurality of second contact plugs 139, a second bit insulating block 142, a second bit through electrode 143, a second slim insulating block 144, a plurality of second slim through electrodes 145, a second interlayer insulating layer 152, a plurality of second interconnections 153, 155 and 157, a fourth insulating bonding layer 162, a plurality of fourth bonding pads 163, a second source line 171, a fifth insulating bonding layer 174, a plurality of fifth bonding pads 175, a third stack structure ST3, a third buried insulating layer 237, a plurality of third contact plugs 239, a plurality of third channel structures CH3, a third interlayer insulating layer 252, a plurality of third interconnections 253 and 255, a sixth insulating bonding layer 262, a plurality of sixth bonding pads 263, and a third source line 271.

The circuit structure CS may include a first page buffer PB1, a first decoder DE1, a second decoder DE2, a third decoder DE3 and a circuit insulating layer 24. Each of the plurality of first bonding pads 29 may be connected to a corresponding one among the first page buffer PB1, the first decoder DE1, the second decoder DE2 and the third decoder DE3.

In an embodiment, the first source line 71, the second source line 171 and the third source line 271 may be disconnected from each other. In an embodiment, one selected among a plurality of first horizontal electrodes 35 may be connected to the first decoder DE1, one selected among a plurality of second horizontal electrodes 135 may be connected to the second decoder DE2, and one selected among a plurality of third horizontal electrodes 235 may be connected to the third decoder DE3.

Referring to FIG. 26, a semiconductor device based on an embodiment of the disclosed technology may include a first substrate 21, a circuit structure CS, a first insulating bonding layer 28, a plurality of first bonding pads 29, a first stack structure ST1, a plurality of first channel structures CH1, a first buried insulating layer 37, a plurality of first contact plugs 39, a first bit insulating block 42, a plurality of first bit through electrodes 43, a first slim insulating block 44, a first slim through electrode 45, a first interlayer insulating layer 52, a plurality of first interconnections 53, 55 and 57, a second insulating bonding layer 62, a plurality of second bonding pads 63, a first source line 71, a third insulating bonding layer 74, a plurality of third bonding pads 75, a plurality of bit contact plugs 75CP, a second stack structure ST2, a plurality of second channel structures CH2, an upper insulating layer 98, a source interconnection 99, a second buried insulating layer 137, a plurality of second contact plugs 139, a second bit insulating block 142, a second bit through electrode 143, a second slim insulating block 144, a second slim through electrode 145, a second interlayer insulating layer 152, a plurality of second interconnections 153, 155 and 157, a fourth insulating bonding layer 162, a plurality of fourth bonding pads 163, a second source line 171, a fifth insulating bonding layer 174, a plurality of fifth bonding pads 175, a third stack structure ST3, a third buried insulating layer 237, a plurality of third contact plugs 239, a plurality of third channel structures CH3, a third interlayer insulating layer 252, a plurality of third interconnections 253 and 255, a sixth insulating bonding layer 262, a plurality of sixth bonding pads 263, and a third source line 271.

The circuit structure CS may include a first page buffer PB1, a second page buffer PB2, a third page buffer PB3, a first decoder DE1 and a circuit insulating layer 24. Each of the plurality of first bonding pads 29 may be connected to a corresponding one among the first page buffer PB1, the second page buffer PB2, the third page buffer PB3 and the first decoder DE1.

In an embodiment, the first source line 71, the second source line 171 and the third source line 271 may be disconnected from each other. In an embodiment, one selected among the plurality of first channel structures CH1 may be connected to the first page buffer PB1, one selected among the plurality of second channel structures CH2 may be connected to the second page buffer PB2, and one selected among the plurality of third channel structures CH3 may be connected to the third page buffer PB3.

Although embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. The spirit and scope of the disclosure should be interpreted in connection with the appended claims and encompass all equivalents falling within the scope of the appended claims.

What is claimed is:

1. A semiconductor device comprising:
a circuit structure including a page buffer;
a first stack structure bonded over the circuit structure, and including a plurality of first insulating layers and a plurality of first horizontal electrodes which are alternately stacked;
a first source line on the first stack structure;
a first channel structure connected to the first source line by passing through the first stack structure;
a second stack structure bonded over the first stack structure and the first source line, and including a plurality of second insulating layers and a plurality of second horizontal electrodes which are alternately stacked;
a second source line on the second stack structure;
a second channel structure connected to the second source line by passing through the second stack structure; and
a first bit through electrode connected to the second channel structure by passing through the first stack structure,
wherein the first channel structure is connected to the page buffer, and
wherein the second channel structure is connected to the page buffer through the first bit through electrode.

2. The semiconductor device according to claim 1, wherein the first bit through electrode is disposed adjacent to the first channel structure.

3. The semiconductor device according to claim 1, further comprising:
a first contact plug connected to one first horizontal electrode selected among the plurality of first horizontal electrodes,
wherein the circuit structure further includes a first decoder connected to the first contact plug.

4. The semiconductor device according to claim 3, wherein each of the page buffer and the first decoder includes at least one transistor.

5. The semiconductor device according to claim 3, further comprising:
a slim through electrode connected to one second horizontal electrode selected among the plurality of second horizontal electrodes by passing through the first stack structure,
wherein the slim through electrode is connected to the first decoder.

6. The semiconductor device according to claim 5, further comprising:
a source through electrode connected to the first source line and the second source line by passing through the second stack structure.

7. The semiconductor device according to claim 6, wherein the source through electrode is disposed adjacent to the second channel structure.

8. The semiconductor device according to claim 7, wherein
the source through electrode extends into the second source line, and
an uppermost end of the source through electrode is disposed at a level higher than a lowermost end of the second source line.

9. The semiconductor device according to claim 3, further comprising:
a slim through electrode connected to one second horizontal electrode selected among the plurality of second horizontal electrodes by passing through the first stack structure,
wherein the circuit structure further includes a second decoder connected to the slim through electrode.

10. The semiconductor device according to claim 1, further comprising:
a first insulating bonding layer on the circuit structure;
a plurality of first bonding pads in the first insulating bonding layer;
a second insulating bonding layer between the first stack structure and the first insulating bonding layer;
a plurality of second bonding pads in the second insulating bonding layer;
a third insulating bonding layer on the first stack structure and the first source line;
a plurality of third bonding pads in the third insulating bonding layer;
a fourth insulating bonding layer between the second stack structure and the third insulating bonding layer; and
a plurality of fourth bonding pads in the fourth insulating bonding layer,
wherein the second insulating bonding layer is bonded over the first insulating bonding layer,
wherein the plurality of second bonding pads are bonded over the plurality of first bonding pads,
wherein the fourth insulating bonding layer is bonded over the third insulating bonding layer, and
wherein the plurality of fourth bonding pads are bonded over the plurality of third bonding pads.

11. The semiconductor device according to claim 10, wherein
one surfaces of the first insulating bonding layer and the plurality of first bonding pads form substantially the same plane,
one surfaces of the second insulating bonding layer and the plurality of second bonding pads form substantially the same plane,
one surfaces of the third insulating bonding layer and the plurality of third bonding pads form substantially the same plane, and
one surfaces of the fourth insulating bonding layer and the plurality of fourth bonding pads form substantially the same plane.

12. The semiconductor device according to claim 10, further comprising:
a bit contact plug passing through the third insulating bonding layer and the first source line, and disposed between one third bonding pad selected among the plurality of third bonding pads and the first bit through electrode.

13. The semiconductor device according to claim 12, wherein an interface between the bit contact plug and the first bit through electrode is disposed between an upper surface and a lower surface of the first source line.

14. The semiconductor device according to claim 1, further comprising:
a third stack structure bonded over the second stack structure and the second source line, and including a plurality of third insulating layers and a plurality of third horizontal electrodes which are alternately stacked;
a third source line on the third stack structure;
a third channel structure connected to the third source line by passing through the third stack structure; and
a second bit through electrode connected to the third channel structure by passing through the second stack structure,
wherein the second bit through electrode is connected to the first bit through electrode, and
wherein the third channel structure is connected to the page buffer through the second bit through electrode and the first bit through electrode.

15. A semiconductor device comprising:
a circuit structure including a decoder;
a first stack structure bonded over the circuit structure, and including a plurality of first insulating layers and a plurality of first horizontal electrodes which are alternately stacked, the first stack structure having a first cell area and a first connection area which is continuous to a side surface of the first cell area;
a first source line on the first stack structure;
a first channel structure connected to the first source line by passing through the first stack structure, and disposed in the first cell area;
a first contact plug disposed in the first connection area, and connected to one first horizontal electrode selected among the plurality of first horizontal electrodes;
a second stack structure bonded over the first stack structure and the first source line, and including a plurality of second insulating layers and a plurality of second horizontal electrodes which are alternately stacked, the second stack structure having a second cell area and a second connection area which is continuous to a side surface of the second cell area;
a second source line on the second stack structure;
a second channel structure connected to the second source line by passing through the second stack structure, and disposed in the second cell area; and
a first slim through electrode connected to one second horizontal electrode selected among the plurality of second horizontal electrodes by passing through the first stack structure,
wherein the first contact plug and the first slim through electrode are connected to the decoder.

16. The semiconductor device according to claim 15, further comprising:
a source through electrode connected to the first source line and the second source line by passing through the second stack structure.

17. The semiconductor device according to claim 15, further comprising:
a third stack structure bonded over the second stack structure and the second source line, and including a plurality of third insulating layers and a plurality of third horizontal electrodes which are alternately stacked, the third stack structure having a third cell area and a third connection area which is continuous to a side surface of the third cell area;
a third source line on the third stack structure;
a third channel structure connected to the third source line by passing through the third stack structure, and disposed in the third cell area; and
a second slim through electrode connected to one third horizontal electrode selected among the plurality of third horizontal electrodes by passing through the second stack structure,
wherein the second slim through electrode is connected to the decoder through the first slim through electrode.

18. The semiconductor device according to claim 15, further comprising:
a bit through electrode connected to the second channel structure by passing through the first stack structure,
wherein the circuit structure further includes first and second page buffers,
wherein the first channel structure is connected to the first page buffer, and
wherein the second channel structure is connected to the second page buffer through the bit through electrode.

19. A semiconductor device comprising:
a circuit structure including a first page buffer;
a first stack structure bonded over the circuit structure, and including a plurality of first insulating layers and a plurality of first horizontal electrodes which are alternately stacked;
a first source line on the first stack structure;
a first channel structure connected to the first source line by passing through the first stack structure;
a second stack structure bonded over the first stack structure and the first source line, and including a plurality of second insulating layers and a plurality of second horizontal electrodes which are alternately stacked;
a second source line on the second stack structure;
a second channel structure connected to the second source line by passing through the second stack structure; and
a first source through electrode connected to the first source line and the second source line by passing through the second stack structure.

20. The semiconductor device according to claim 19, further comprising:
a bit through electrode connected to the second channel structure by passing through the first stack structure,
wherein the first channel structure is connected to the first page buffer, and
wherein the second channel structure is connected to the first page buffer through the bit through electrode.

21. The semiconductor device according to claim 19, further comprising:
a third stack structure bonded over the second stack structure and the second source line, and including a plurality of third insulating layers and a plurality of third horizontal electrodes which are alternately stacked;
a third source line on the third stack structure;
a third channel structure connected to the third source line by passing through the third stack structure; and
a second source through electrode connected to the second source line and the third source line by passing through the third stack structure.

22. The semiconductor device according to claim 19, further comprising:
a bit through electrode connected to the second channel structure by passing through the first stack structure; and
a slim through electrode connected to one second horizontal electrode selected among the plurality of second horizontal electrodes by passing through the first stack structure,
wherein the circuit structure further includes a second page buffer and first and second decoders,
wherein the first channel structure is connected to the first page buffer,
wherein the second channel structure is connected to the second page buffer through the bit through electrode,
wherein one first horizontal electrode selected among the plurality of first horizontal electrodes is connected to the first decoder, and
wherein one second horizontal electrode is selected among the plurality of second horizontal electrodes is connected to the second decoder through the slim through electrode.
